(19) United States
(12) Patent Application Publication
(10) Pub. No.: US 2026/0107554 A1
(43) Pub. Date: Apr. 16, 2026

(54) SEMICONDUCTOR DEVICES AND METHODS OF FORMING THE SAME

(71) Applicant: Taiwan Semiconductor Manufacturing Company, Ltd., Hsin-Chu (TW)

(72) Inventors: Ping-Wei Wang, Hsin-Chu (TW); Chih-Hsuan Chen, Hsinchu (TW); Jui-Lin Chen, New Taipei City (TW)

(21) Appl. No.: 19/086,993

(22) Filed: Mar. 21, 2025

Related U.S. Application Data
(60) Provisional application No. 63/706,349, filed on Oct. 11, 2024.

(51) Int. Cl. H10D 84/01; H01L 21/265; H10D 64/01; H10D 84/83

(52) U.S. Cl. CPC H10D 84/0142; H10D 64/017; H10D 84/832; H10P 30/204; H10P 30/21

(57) ABSTRACT

Semiconductor devices and methods are provided. An exemplary method includes forming a first fin and a second fin, each of the first fin and the second fin comprising a plurality of channel layers interleaved by a plurality of sacrificial layers, forming a first gate stack and a second gate stack over the first fin and the second fin, respectively, the first gate stack and the second gate stack having different gate lengths, forming a first source/drain feature adjacent to the first gate stack and a second source/drain feature adjacent to the second gate stack, after forming the second source/drain feature, performing an ion implantation process to increase a dopant concentration of an upper portion of the second source/drain feature.

### PRIORITY DATA

This application claims priority to U.S. Provisional Patent Application Ser. No. 63/706,349, filed Oct. 11, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. Integrated circuits include a variety of circuit device components, such as transistors. Transistors with different configurations may be suitable for different circuit functions due to their different performance characteristics.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a diagrammatic plan view of a semiconductor device, in portion or entirety, according to various aspects of the present disclosure.

FIG. 2A is a diagrammatic plan view of an array of memory cells, such as static random-access memory (SRAM) cells, in portion or entirety, according to various aspects of the present disclosure.

FIG. 2B is a circuit diagram of a memory cell, such as an SRAM cell, that can be implemented in the IC chip of FIG. 1, according to various aspects of the present disclosure.

FIG. 3 illustrates a fragmentary layout of a portion of the semiconductor device shown in FIG. 1, according to various aspects of the present disclosure.

FIG. 4 illustrates a flow chart of a method for forming the semiconductor device including the SRAM cell and a logic circuit, according to one or more aspects of the present disclosure.

FIGS. 5, 7, 9, 10, 18 illustrate fragmentary top views of the semiconductor device during various fabrication stages in the method of FIG. 4, according to one or more aspects of the present disclosure.

FIGS. 6A, 8A, 11A, 12A, 13A, 14A, 15A, 16A, 17A, 19A illustrate fragmentary cross-sectional views of the semiconductor device taken along line A-A′ shown in FIG. 5 during various fabrication stages in the method of FIG. 4, according to one or more aspects of the present disclosure.

FIGS. 6B, 8B, 11B, 12B, 13B, 14B, 15B, 16B, 17B, 19B illustrate fragmentary cross-sectional views of the semiconductor device taken along line B-B′ shown in FIG. 5 during various fabrication stages in the method of FIG. 4, according to one or more aspects of the present disclosure.

FIGS. 6C, 8C, 11C, 12C, 13C, 14C, 15C, 16C, 17C, 19C illustrate fragmentary cross-sectional views of the semiconductor device taken along line C-C′ shown in FIG. 5 during various fabrication stages in the method of FIG. 4, according to one or more aspects of the present disclosure.

FIGS. 6D, 15D, 16D illustrate fragmentary cross-sectional views of the semiconductor device taken along line D-D′ shown in FIG. 5 during various fabrication stages in the method of FIG. 4, according to one or more aspects of the present disclosure.

FIGS. 6E, 15E, 16E illustrate fragmentary cross-sectional views of the semiconductor device taken along line E-E′ shown in FIG. 5 during various fabrication stages in the method of FIG. 4, according to one or more aspects of the present disclosure.

FIG. 20 illustrates a dopant concentration profile of a source/drain feature, according to one or more aspects of the present disclosure.

FIG. 21 depicts simulation results for frequencies of ring oscillators that include transistors fabricated using the method of FIG. 4.

FIGS. 22A, 22B, 22C, 22D, 23A, 23B, 23C illustrate fragmentary cross-sectional views of the semiconductor device during various fabrication stages in the method of FIG. 4, according to a first alternative embodiment of the present disclosure.

FIGS. 24A, 24B, 24C, 25A, 25B, 25C illustrate fragmentary cross-sectional views of the semiconductor device during various fabrication stages in the method of FIG. 4, according to a second alternative embodiment of the present disclosure.

FIGS. 26A, 26B, 26C, 27A, 27B, 27C illustrate fragmentary cross-sectional views of the semiconductor device during various fabrication stages in the method of FIG. 4, according to a third alternative embodiment of the present disclosure.

FIG. 28 illustrates a fragmentary top view of the logic circuit, according to a fourth alternative embodiment of the present disclosure.

FIG. 29 illustrates a fragmentary top view of the logic circuit, according to a fifth alternative embodiment of the present disclosure.

FIG. 30 illustrates a fragmentary cross-sectional view of the logic circuit taken along line F-F′ shown in FIG. 29, according to a third alternative embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for case of the present disclosure of one features relationship to another feature. The spatially relative terms are intended to cover different orientations of the device including the features.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

An integrated circuit includes a memory device and some logic circuits. During operation, the memory device and the logic circuits may need different improved performances. For instance, the logic circuits may prefer to have a higher speed (e.g., better ring oscillator speed), and the memory device may prefer to have a better voltage stability, less threshold voltage (Vt) variation, less operation voltage (e.g., V_{ccmin}). An exemplary static random-access memory (SRAM) cell includes both n-type transistors and p-type transistors. An n-type transistor (e.g., NFET) includes a pair of n-type doped source/drain features, and its majority carrier is electrons. A p-type transistor (PFET) includes a pair of p-type doped source/drain features, and its majority carrier is holes. For NFETs (e.g., pull-down transistors and pass-gate transistors in the SRAM cell) and PFETs (e.g., pull-up transistors) have same configurations (e.g., effective channel widths, effective channel thicknesses, gate lengths), PFETs may have better performance than NFETs. “Alpha ratio” of the saturation current, that is the ratio of Iₛₐₜ of pull-up transistors to Iₛₐₜ of pull-down transistors, affects various aspects (e.g., cell current, operation voltage V_{ccmin}, write margin, read margin, operation speed) of the performance of the SRAM cell. The present disclosure provides solutions to improve both performance (e.g., speed) of the logic circuits and performance (e.g., less threshold voltage (Vt) variation, write margin, V_{ccmin}) of the memory devices.

The various aspects of the present disclosure will now be described in more detail with reference to the figures. For avoidance of doubts, the X-axis, Y-axis and Z-axis in the figures are perpendicular to one another and are used consistently throughout the present disclosure. Throughout the present disclosure, like reference numerals denote like features unless otherwise excepted.

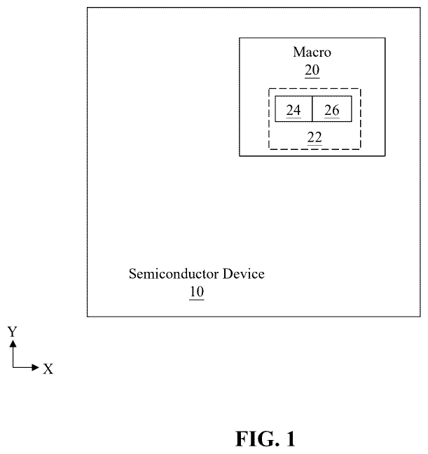

Reference now is made to FIG. 1. FIG. 1 is a simplified block diagram of a semiconductor device (or IC) 10, in accordance with some embodiments of the present disclosure. The semiconductor device 10 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistors (PFETs), n-type field effect transistors (NFETs), FinFET, gate-all-around (GAA) transistors (such as nanosheet FETs or nanowire FETs), other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the semiconductor device 10 is not a limitation to the provided subject matter.

The semiconductor device 10 includes a memory macro (hereinafter, macro) 20. In some embodiments, the macro 20 is a static random-access memory (SRAM) macro, such as a single-port SRAM macro, a dual-port SRAM macro, or other types of SRAM macro. However, the present disclosure contemplates embodiments, where macro 20 is another type of memory, such as a dynamic random-access memory (DRAM), a non-volatile random access memory (NVRAM), a flash memory, or other suitable memory. FIG. 1 has been simplified for the sake of clarity to better understand the inventive concepts of the present disclosure. Additional features can be added in the macro 20, and some of the features described below can be replaced, modified, or eliminated in other embodiments of the macro 20.

In some embodiments, the macro 20 includes memory cells and peripheral circuits. The memory cells are also referred to as bit cells, and are configured to store memory bits. The peripheral cells are also referred to as logic cells that are disposed around the bit cells, and are configured to implement various logic functions. The logic functions of the logic cells include, for example, write and/or read decoding, word line selecting, bit line selecting, data driving and memory self-testing. The logic functions of the logic cells described above are given for the explanation purpose. Various logic functions of the logic cells are within the contemplated scope of the present disclosure. In the illustrated embodiment, the macro 20 includes a circuit region 22 in which at least a memory array 24 and at least a peripheral circuit (or “logic circuit”) 26 are positioned in close proximity to each other. The memory array 24 includes many memory cells arranged in rows and columns. The peripheral circuit 26 includes logic cells. Generally, the peripheral circuit 26 may include many logic cells to provide read operations and/or write operations to the memory cells in the memory array 24. The macro 20 may include more than one memory array 24 and more than one peripheral circuit 26. Transistors in the one or more memory arrays 24 and the one or more peripheral circuits 26 may be implemented with various PFETs and NFETs such as planar transistors or non-planar transistors including various FinFET transistors, GAA transistors, or a combination thereof. GAA transistors refer to transistors having gate electrodes surrounding transistor channels, such as vertically-stacked gate-all-around horizontal nanowire or nanosheet MOSFET devices. The following disclosure will continue with one or more GAA examples to illustrate various embodiments of the present disclosure. It is understood, however, that the application should not be limited to a particular type of device, except as specifically claimed.

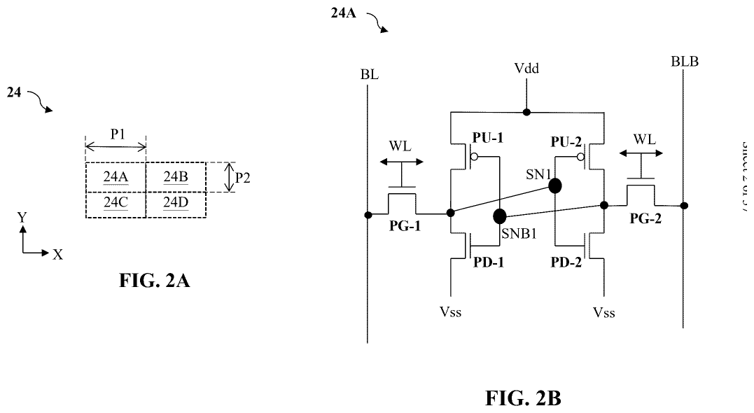

In the present embodiments, referring to FIG. 2A, the memory array 24 includes a number of SRAM cells (such as SRAM cells 24A, 24B, 24C, and 24D shown in FIG. 2A), which generally provide memory or storage capable of retaining data when power is applied. As such, the memory array 24 is hereafter referred to as an SRAM array 24. In the present embodiments, each of the SRAM cells 24A-24D includes one or more GAA transistors to be discussed in detail below. In the present embodiments, still referring to FIG. 2A, the SRAM cells 24A, 24B, 24C, and 24D, together defining a two-by-two grid, exhibit mirror and/or rotational symmetry with respect to each other. For example, using the SRAM cell 24C as a reference, a layout of the SRAM cell 24A is a mirror image of a layout of the SRAM cell 24C with respect to the X-axis. Similarly, a layout of the SRAM cell 24B is a mirror image of the layout of the SRAM cell 24A, and a layout of the SRAM cell 24D is a mirror image of the layout of the SRAM cell 24C, both with respect to the Y-axis. In other words, the layout of the SRAM cell 24B is symmetric to the layout of the SRAM cell 24C by a rotation of 180 degrees about a geometric center of the grid, which is defined as an intersection point of an imaginary line bisecting the rectangular grid along the Y-axis and an imaginary line bisecting the rectangular grid along the X-axis. Furthermore, in the depicted embodiments, the SRAM cells 24A-24D are substantially the same in size, i.e., having substantially the same horizontal (long) pitch P1 along the X-axis and a vertical (short) pitch P2 along the Y-axis.

FIG. 2B illustrates an example circuit schematic for the SRAM cell 24A. The SRAM cell 2A includes pull-up transistors PU-1, PU-2; pull-down transistors PD-1, PD-2; and pass-gate transistors PG-1, PG-2. As shown in the circuit diagram, transistors PU-1 and PU-2 are p-type transistors, and transistors PG-1, PG-2, PD-1, and PD-2 are n-type transistors. Since the SRAM cell 24A includes six transistors in the illustrated embodiment, it may also be referred to as a 6T SRAM cell 24A. The drains of pull-up transistor PU-1 and pull-down transistor PD-1 are coupled together, and the drains of pull-up transistor PU-2 and pull-down transistor PD-2 are coupled together. Transistors PU-1 and PD-1 are cross-coupled with transistors PU-2 and PD-2 to form a data latch. The gates of transistors PU-2 and PD-2 are coupled together and to the drains of transistors PU-1 and PD-1 to form a first storage node SN1, and the gates of transistors PU-1 and PD-1 are coupled together and to the drains of transistors PU-2 and PD-2 to form a complementary first storage node SNB1. Sources of the pull-up transistors PU-1 and PU-2 are coupled to a power voltage Vdd, and the sources of the pull-down transistors PD-1 and PD-2 are coupled to a voltage Vss, which may be an electrical ground in some embodiments. The first storage node SN1 of the data latch is coupled to bit line BL through pass-gate transistor PG-1, and the complementary first storage node SNB1 is coupled to complementary bit line BLB through pass-gate transistor PG-2. The first storage node SN1 and the complementary first storage node SNB1 are complementary nodes that are often at opposite logic levels (logic high or logic low). Gates of pass-gate transistors PG-1 and PG-2 are coupled to a word line WL. In the illustrated embodiment, the pass-gate transistors PG1-1 and PG-2 and pull-down transistors PD-1 and PD-2 are n-type transistors, and the pull-up transistors PU-1 and PU-2 are p-type transistors.

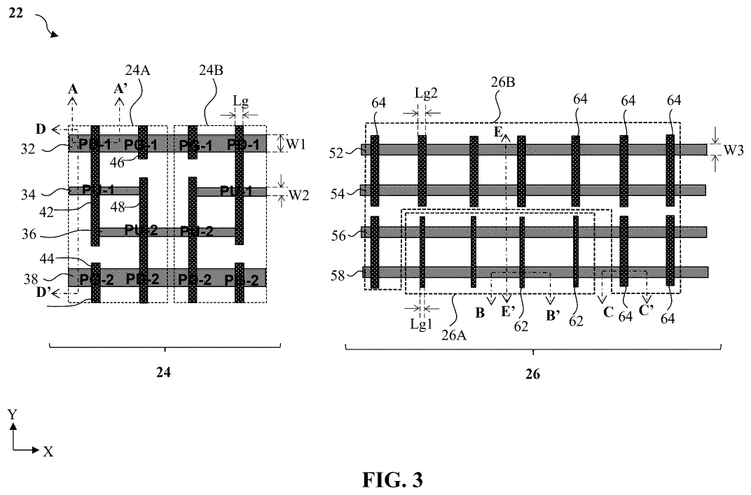

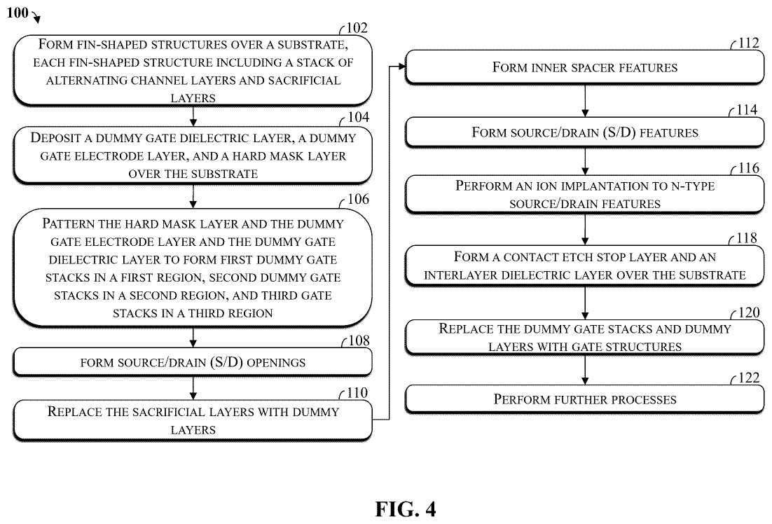

FIG. 3 illustrates a fragmentary layout view of the circuit region 22 that includes the memory array 24 and the peripheral circuit 26 positioned in close proximity to each other. With respect to the memory array 24, two adjacent SRAM cells 24A and 24B are shown. A boundary of the SRAM cell 24A is illustrated using broken lines. In the present embodiments represented in FIG. 3, the SRAM cell 24A includes two active regions 32 and 38 each disposed over a p well (not shown) and two active regions 34 and 36 each disposed over an n well (not shown) interposing between the two p wells. The active regions 32, 34, 36, and 38 each extend lengthwise along the X-axis. The SRAM cell 24A also includes a number of gate structures, such as gate structures 42, 44, 46, 48, oriented lengthwise along the Y-axis and overlapping the active regions 32 and 38 and/or the active regions 34 and 36 to form various transistors (e.g., PU-1, PU-2, PD-1, PD-2, PG-1, PG-2). Each of the gate structures 42-48 traverses channel region(s) of active regions. In the depicted embodiments, referring to FIG. 3 as an example, the gate structure 42 and the active region 32 form a portion of the pull-down transistor PD-1, the gate structure 42 and the active region 34 form a portion of the pull-up transistor PU-1, the gate structure 44 and the active region 38 form a portion of the pass-gate transistor PG-2, the gate structure 46 and the active region 32 form a portion of the pass-gate transistor PG-1, the gate structure 48 and the active region 36 form a portion of the pull-up transistor PU-2, the gate structure 48 and the active region 38 form a portion of the pull-down transistor PD-2. In some embodiments, the pull-up transistor PU-1 and the PU-2 are configured as p-type transistors, while the pull-down transistor PD-1 and PD-2 and the pass-gate transistors PG-1 and PG-2 are configured as n-type transistors. In some embodiments, the active regions 32 and 38 for forming n-type transistors have a channel width W1 greater than a channel width W2 of the active regions 34 and 36 for forming p-type transistors. The gate structures 42, 44, 46, and 48 may have a same gate length Lg. As illustrated by FIG. 3, to form a SRAM cell with desired function, the gate structures 42 and 44 are physically isolated, and the gate structures 46 and 48 are physically isolated. The isolation may be provided by gate isolation structures. The layout of the SRAM cell 24B is a mirror image of the layout of the SRAM cell 24A and repeated description of the SRAM cell 24B is omitted for reason of simplicity. In the present embodiment, performances of the n-type transistors (e.g., the pull-down transistors and pass-gate transistors) will be boosted to increase the saturation current of the n-type transistors. Details of the methods of forming SRAM cells with boosted performance (e.g., balanced threshold voltage, higher speed, better write margin) will be described below with reference to FIG. 4, FIGS. 5-15E and FIGS. 22A-27C.

A fragmentary layout of the peripheral circuit 26 is also shown in FIG. 3. In this illustrated embodiment, the peripheral circuit 26 includes active regions 52, 54, 56, and 58 extending lengthwise along the X-axis. Each of the active regions 52, 54, 56, and 58 can be used to form either n-type transistors or p-type transistors, depending on the design requirement of the peripheral circuit 26. In an embodiment, the active regions 52, 54, 56, and 58 have a channel width W3. The channel width W3 may be less than the width W1 and greater than the width W2. The peripheral circuit 26 includes two types of gate structures 62 and 64 oriented lengthwise along the Y-axis and overlapping at least one of the active regions 52, 54, 56, and 58 to form various transistors. Each of the gate structures 62 and 64 traverses channel region(s) of active regions. More specifically, the peripheral circuit 26 includes a first region 26A having first-type gate structures 62 and a second region 26B having second-type gate structures 64. The first-type gate structures 62 have a gate length Lg1 less than a gate length Lg2 of the second-type gate structures 64. A path is defined as a route to distribute signal in a circuit. A critical path is the place that mainly dominates the circuit speed (or signal distribution speed) that is dependent on different circuit applications. If the circuit speed is varied with transistors' performance significantly, then the path will be referred to as critical path; if the circuit speed is not substantially associated with transistors' performance, then the path will be referred to as a non-critical path. In an embodiment, the first region 26A may include transistors in a critical path, and the second region 26B may include transistors in a non-critical path. It is beneficial to make the critical path and the non-critical path have different configurations during field operations to reduce power consumption while maintaining satisfactory circuit speed. In this illustrated implementation, to obtain a higher on current Iₒₙ and a higher speed, the transistors in the first region 26A are configured to have the gate length Lg1 less than the gate length Lg2 of the transistors in the second region 26B. Details of the formation of the peripheral circuit 26 with improved performance will be described with reference to FIGS. 4-30. In that regard, FIG. 4 is a flowchart illustrating method 100 of forming the circuit region 22, according to embodiments of the present disclosure. Method 100 is described below in conjunction with FIGS. 5-30, which are fragmentary cross-sectional views or top views of a semiconductor structure 200 at different stages of fabrication according to embodiments of method 100. Upon completion of the operations of method 100, the semiconductor structure 200 may be a portion of the circuit region 22.

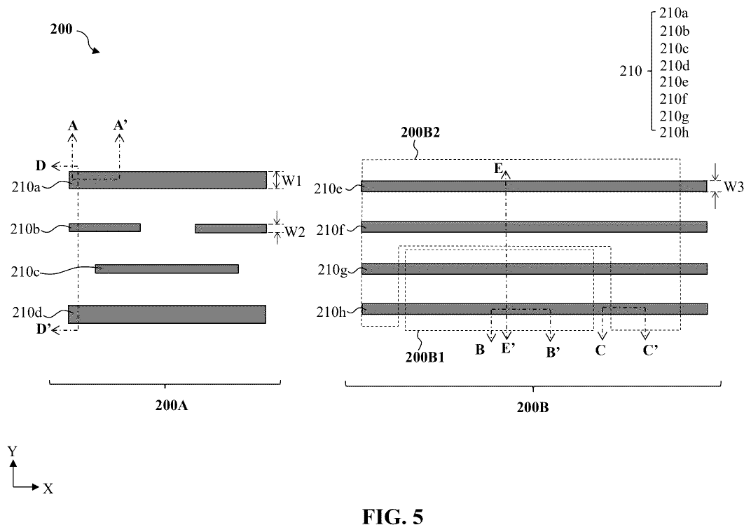

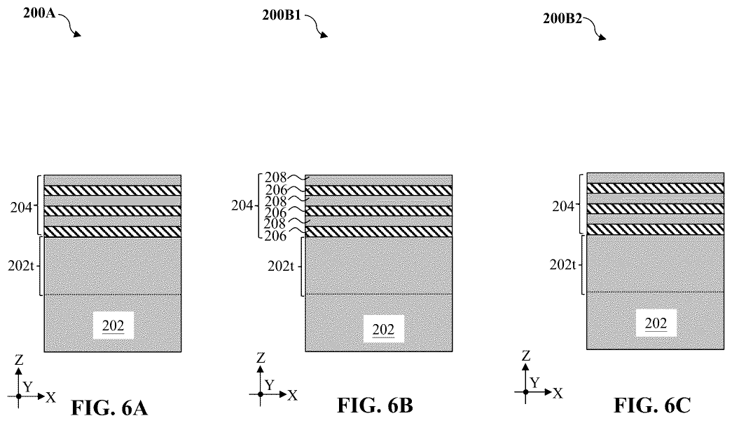

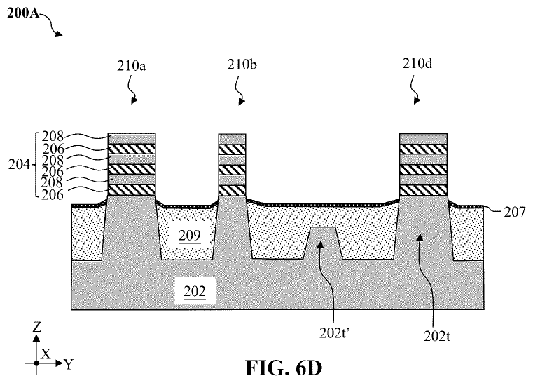

Referring to FIGS. 4-5 and 6A-6E, method 100 includes a block 102 where fin-shaped structures 210 are formed over a substrate 202. FIG. 5 depicts a fragmentary top view of the semiconductor structure 200 including the fin-shaped structures 210. FIGS. 6A, 6B, 6C, 6D, 6E depict fragmentary cross-sectional views of the semiconductor structure 200 taken along line A-A′, B-B′, C-C′, D-D′, and E-E′ shown in FIG. 5, respectively. In one embodiment, the substrate 202 (shown in FIGS. 6A-6E) is a silicon (Si) substrate. In some other embodiments, the substrate 202 may include other semiconductors such as germanium (Ge), silicon germanium (SiGe), or a III-V semiconductor material. Exemplary III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GainP), and indium gallium arsenide (InGaAs). The substrate 202 may also include an insulating layer, such as a silicon oxide layer, to have a semiconductor-on-insulator (SOI) structure. Although not explicitly shown in the figures, the substrate 202 may include one or more n-type well regions and one or more p-type well regions for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The fin-shaped structures 210 are then formed to protrude from the substrate 202. In this embodiment, the fin-shaped structures 210 include fin-shaped structures 210a, 210b, 210c, and 210d formed in a region 200A of the semiconductor structure 200. The region 200A of the semiconductor structure 200 will be fabricated to form the portion of the memory array 24 described above with reference to FIG. 3. The fin-shaped structures 210 also include fin-shaped structures 210c, 210f, 210g, and 210h formed in a region 200B of the semiconductor structure 200. The region 200B of the semiconductor structure 200 will be fabricated to form the portion of the peripheral circuit 26 described above with reference to FIG. 3. The fin-shaped structures 210a, 210b, 210c, 210d, 210c, 210f, 210g, and 210h may be individually and collectively referred to as the fin-shaped structure(s) 210. In the illustrated embodiment, the region 200B includes a first part 200B1 configured to form the first region 26A and a second part 200B2 configured to form the second region 26B. To avoid confusion, the first part 200B1 of the region 200B may also be referred to as the region 200B1, and the second part 200B2 of the region 200B may also be referred to as the region 200B2.

An exemplary process for forming the fin-shaped structures 210 includes forming a stack 204 over the substrate 202. The stack 204 includes a number of sacrificial layers 206 and a number of channel layers 208 interleaved by the number of sacrificial layers 206. The channel layers 208 and the sacrificial layers 206 include different materials to provide etch selectivity. Each channel layer 208 may include a semiconductor material such as, for example, Si, Ge, SiC, SiGe, GeSn, SiGeSn, SiGeCSn, other suitable semiconductor materials, or combinations thereof, while each sacrificial layer 206 has a material different from that of the channel layer 208. In one such example, the channel layers 208 may include elemental Si and the sacrificial layers 206 may include SiGe. The sacrificial layers 206 and channel layers 208 may be deposited using an epitaxial process. Suitable epitaxial processes include vapor-phase epitaxy (VPE), ultra-high vacuum chemical vapor deposition (UHV-CVD), molecular beam epitaxy (MBE), and/or other suitable processes. As shown in FIGS. 6A-6E, the sacrificial layers 206 and the channel layers 208 are deposited alternatingly, one-after-another, to form the stack 204. It is noted that three layers of the sacrificial layers 206 and three layers of the channel layers 208 are alternately and vertically arranged as illustrated in FIGS. 6A-6E, which are for illustrative purposes only and not intended to be limiting beyond what is specifically recited in the claims. It is understood that any number of sacrificial layers and channel layers can be formed in the stack 204. The number of layers depends on the desired number of channels members for the device 20. In some embodiments, the number of the channel layers 208 is between 2 and 10, and the number of the sacrificial layers 206 is between 2 and 10. After forming the stack 204, the stack 204 and a top portion of the substrate 202 are patterned to form the fin-shaped structures 210. The top portion of the substrate 202 that is patterned during the formation of the active regions may be referred to as a protrusion 202t, a base portion 202t, a base fin 202t, or a mesa structure 202t. In the cross-sectional view represented by FIG. 6D, to form SRAM cells with desired functions, a part 202t′ of the base fin 202t of the active region 210c is recessed. The recessed part 202t′ of the base fin 202t has a height less than a height of a remaining part of the base fin 202t.

Isolation features, such as the isolation features 209 (e.g., a shallow trench isolation (STI) feature) shown in FIGS. 6D-6E, are subsequently formed to provide isolation between two adjacent fin-shaped structures 210. The isolation feature 209 may include silicon oxide, silicon oxynitride, fluorine-doped silicate glass (FSG), a low-k dielectric, combinations thereof, and/or other suitable materials. In this illustrated embodiment, the isolation feature 209 extends over the recessed part 202t′ of the base fin 202t of the fin-shaped structure 210c. In some embodiments, a top surface of the isolation feature 209 is lower than a top surface of the top portion 202t of the substrate 202. The top surface of the isolation feature 209 may be a curved (e.g., concave) surface having a lowest point near its middle. In an illustrated embodiment, one of the isolation features 209 is disposed between the fin-shaped structure 210a and the fin-shaped structure 210b, and a top surface of the isolation feature 209 includes a first portion adjacent the fin-shaped structure 210a and a second portion equidistant from the fin-shaped structure 210a and the fin-shaped structure 210b, and the first portion is higher than the second portion. The isolation feature 209 interfaces a sidewall of the base fin 202t of the fin-shaped structure 210a and a sidewall of the base fin 202t of the fin-shaped structure 210b. In some embodiments, to prevent the isolation feature 209 from being substantially etched during subsequent processes (e.g., removal of dummy layers 224 performed at block 110), a protection layer 207 is formed on the isolation feature 209. For example, the isolation feature 209 may include silicon oxide, and the protection layer 207 may include silicon nitride.

Referring to FIGS. 4, 7 and 8A-8C, method 100 includes a block 104 where a dummy gate dielectric layer 211, a dummy gate electrode layer 212, and a hard mask layer 213 are deposited over the substrate 202. In an embodiment, the dummy gate dielectric layer 211 may include a suitable dielectric material (e.g., SiO and/or SiO₂, SiON, etc.) and may be formed by thermal oxidation, chemical vapor deposition (CVD), physical vapor deposition (PVD), or other suitable processes. The dummy gate electrode layer 212 is then deposited over the dummy gate dielectric layer 211 and may include polysilicon (poly-Si). Other materials may also be applicable for the present embodiments. In the present embodiments, to accommodate the patterning process and protect the dummy gate electrode layer 212 during subsequent fabrication processes, a hard mask (HM) layer 213, which includes a multi-layer structure, is formed over the dummy gate electrode layer 212. In some embodiments, although not shown, the HM layer 213 includes a bottom HM layer over the dummy gate electrode layer 212 and a top HM layer over the bottom HM layer. In the present embodiments, the bottom HM layer includes a nitride material, such as SiN, and top HM layer includes an oxide material, such as SiO and/or SiO₂. In some embodiments, the layers of the HM layer 213 differ in thickness. In one non-limiting example, a thickness of the bottom HM layer is less than a thickness of the top HM layer.

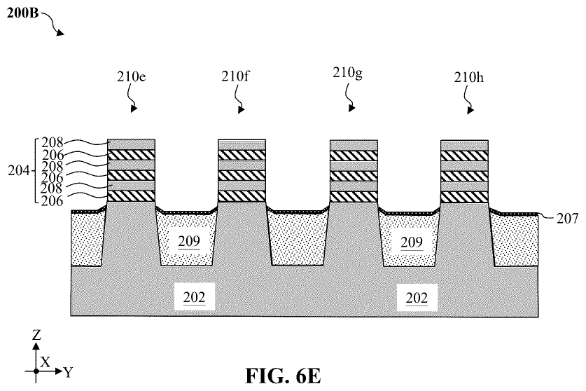

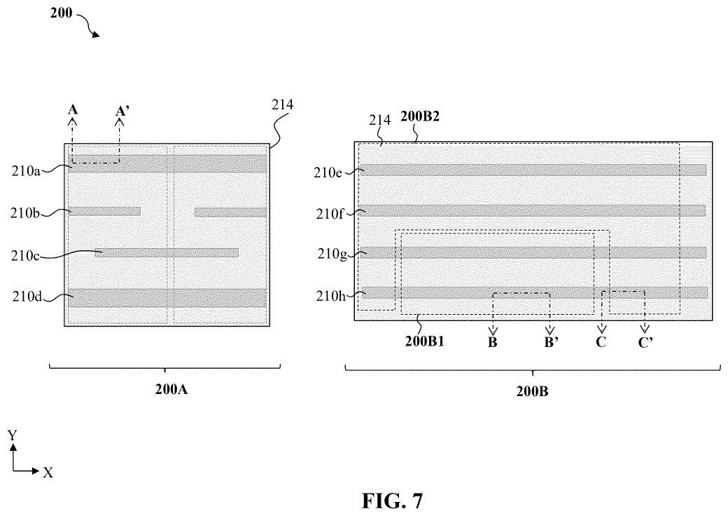

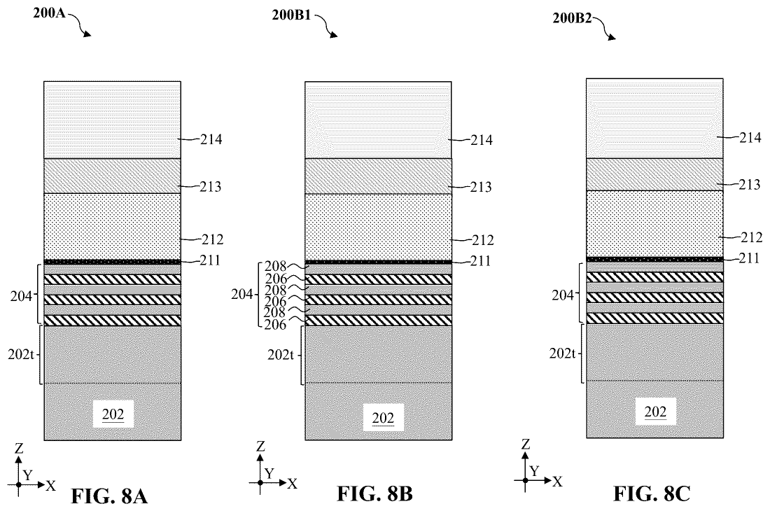

Referring to FIGS. 4 and 7-11C, method 100 includes a block 106 where hard mask layer 213, the dummy gate electrode layer 212, and the dummy gate dielectric layer 211 are patterned to form dummy gate stacks 216. With reference to FIGS. 7 and 8A-8C, a masking element 214 is formed over the HM layer 213. FIG. 7 depicts a fragmentary top view of the semiconductor structure 200 including the masking element 214. FIGS. 8A-8C depict fragmentary cross-sectional views of the semiconductor structure 200 taken along line A-A′, B-B′, C-C′ shown in FIG. 7, respectively. In an embodiment, the masking element 214 includes a multi-layer structure configured to form a patterned feature using a photolithography process. As will be discussed in detail below, the masking element 214 may be patterned using an extreme ultraviolet lithography (EUVL) process. In some embodiments, the masking element 214 may include a photoresist (PR) layer. In the present embodiments, the PR layer includes a resist material sensitive to a EUV radiation source. Regions of the PR layer exposed to the radiation source undergo chemical reactions such that they decompose and become more soluble in a developing solution (i.e., the PR layer undergoes a positive-tone development process). In some embodiments, exposed regions of the PR layer undergo chemical reactions such that they polymerize and/or crosslink and become less soluble in a developing solution (i.e., the PR layer 246 undergoes a negative-tone development process).

With reference to FIG. 9, a photolithography process is performed to pattern the masking element 214. FIG. 9 depicts a fragmentary top view of the semiconductor structure 200 after patterning the masking element 214. In the present embodiments, performing the photolithography process includes exposing the masking element 214 to a radiation source via a photomask. In the present embodiments, the radiation source implemented at block 106 is a EUV radiation having a wavelength of about 1 nm and about 100 nm, and the exposure process is performed in a EUVL system. Correspondingly, a reflective photomask may be used to pattern the masking element 214. The exposed masking element 214 is then developed to form a patterned masking element 214′ that includes structures 214a, 214b, and 214c. The structures 214a, 214b, 214c are continuous and extend lengthwise along the Y-axis. In this embodiment, the structures 214a, 214b, 214c have different widths. The structures 214a are formed in the region 200A, the structures 214b are formed in the region 200B1, and the structures 214c extend cross both the region 200B1 and the region 200B2. In this embodiment, portions of the structures 214a formed over the at least one of the fin-shaped structures 210a-210d have a uniform width D1. Portions of the structures 214b formed over at least one of the fin-shaped structures 210e-210h have a uniform width D2. Portions 214cl of the structures 214c formed over at least one of the fin-shaped structures 210c-210h in the region 200B1 have a width D3, portions 214c2 of the structures 214c formed over the fin-shaped structures 210c-210h in the region 200B2 have the width D2 greater than the width D3. That is, when viewed from top, the structure 210a has a uniform width D1, the structure 210b has a uniform width D2, and the structure 210c has a non-uniform width (e.g., width D2 in the region 200B2 and width D3 in the region 200B1).

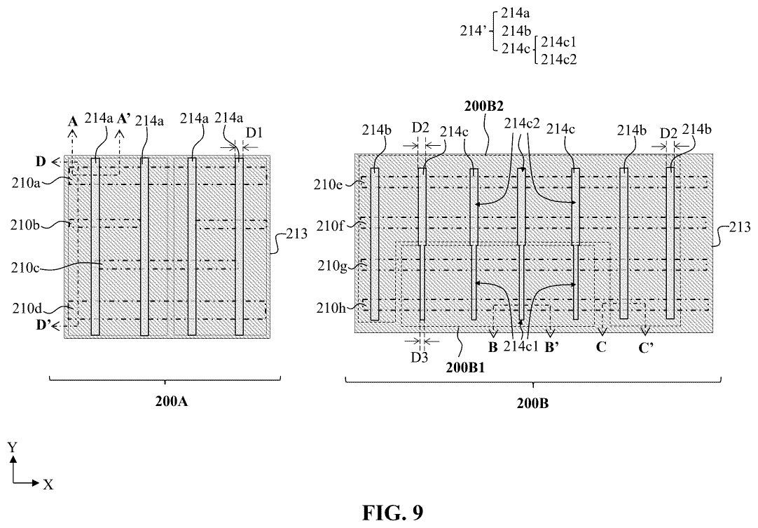

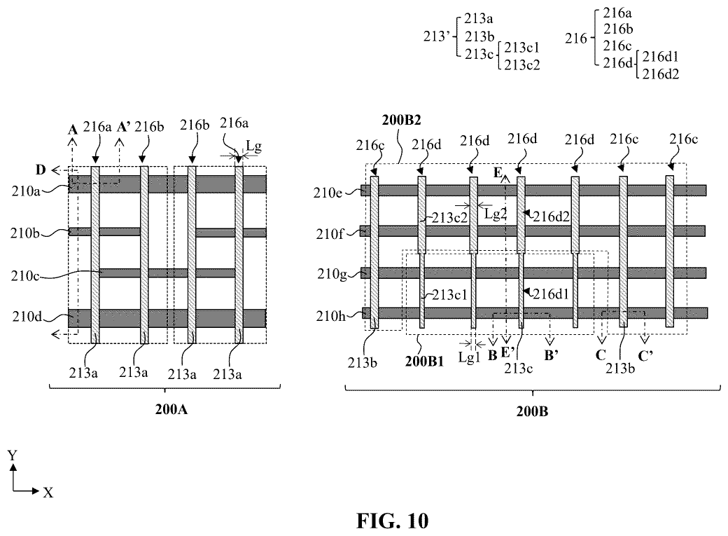

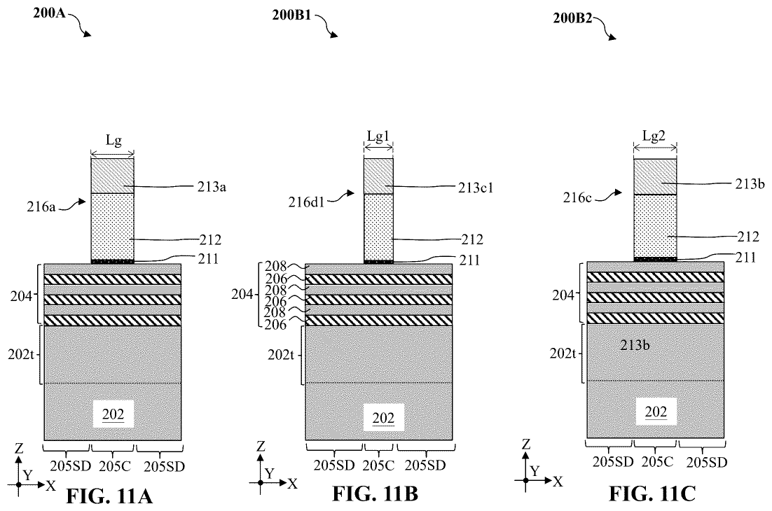

With reference to FIG. 10 and FIGS. 11A-11C, the masking element 214′ that includes the structures 214a-214c is then used to pattern the HM layer 213. FIG. 10 depicts a fragmentary top view of the semiconductor structure 200 after patterning the HM layer 213. FIGS. 11A-11C depict fragmentary cross-sectional views of the semiconductor structure 200 taken along line A-A′, B-B′, C-C′ shown in FIG. 10, respectively. While using the patterned masking element 214′ as an etch mask, an etching process is performed to pattern the HM layer 213. After patterning the HM layer 213, the patterned masking element 214′ is removed from the semiconductor structure 200 by any suitable method, such as resist stripping and/or plasma ashing. The patterned HM layer 213 may be referred to as the HM layer 213′. The HM layer 213′ has a profile similar to that of the patterned masking element 214′ thereover. More specifically, as shown in FIG. 10, the HM layer 213′ includes first portions 213a formed in the region 200A and having the substantially uniform width D1. The HM layer 213′ also includes second portions 213b formed in the region 200B2 and having the substantially uniform width D2. The HM layer 213′ also includes third portions 213c each having a first part 213cl in the region 200B1 and having the width D3 and a second part 213c2 in the region 200B2 and having the width D2 greater than the width D3.

Subsequently, referring to FIGS. 10 and FIGS. 11A-11C, the HM layer 213′ is then used to pattern the dummy gate electrode layer 212 and the dummy gate dielectric layer 211, thereby forming dummy gate stacks 216. FIG. 10 depicts a fragmentary top view of the semiconductor structure 200 after forming the dummy gate stacks 216. FIGS. 11A-11C depict fragmentary cross-sectional views of the semiconductor structure 200 taken along line A-A′, B-B′, C-C′ shown in FIG. 10, respectively. While using the HM layer 213′ as an etch mask, the dummy gate electrode layer 212 and the dummy gate dielectric layer 211 are patterned. One or more etching processes that include a dry etching, a wet etching, or a combination thereof may be implemented to pattern the dummy gate electrode layer 212 and the dummy gate dielectric layer 211. Each of the dummy gate stacks 216 includes a corresponding portion of the patterned HM layer 213′, a corresponding portion of the patterned dummy gate electrode layer 212, and a corresponding portion of the dummy gate dielectric layer 211.

The dummy gate stacks 216 include dummy gate stacks 216a and 216b (shown in FIG. 10) formed in the region 200A. The dummy gate stacks 216a and 216b are formed while using the first portions 213a of the HM layer 213′ as an etch mask. The dummy gate stacks 216a and 216b have the uniform gate length Lg (shown in FIGS. 3 and 10) that may be substantially equal to or less than the width D1. The dummy gate stack 216a is formed over channel regions 205C of the fin-shaped structures 210a, 210b, and 210d. The dummy gate stack 216b is formed over channel regions 205C of the fin-shaped structures 210a, 210c, and 210d.

The dummy gate stacks 216 also include dummy gate stacks 216c (shown in FIG. 10) formed in the region 200B2. The dummy gate stacks 216c are formed while using the second portions 213b of the HM layer 213′ as an etch mask. The dummy gate stacks 216c have the uniform gate length Lg2 (shown in FIGS. 3 and 10) that may be substantially equal to or less than the width D2. The dummy gate stack 216c is formed over channel region 205C of at least one of the fin-shaped structures 210c-210h.

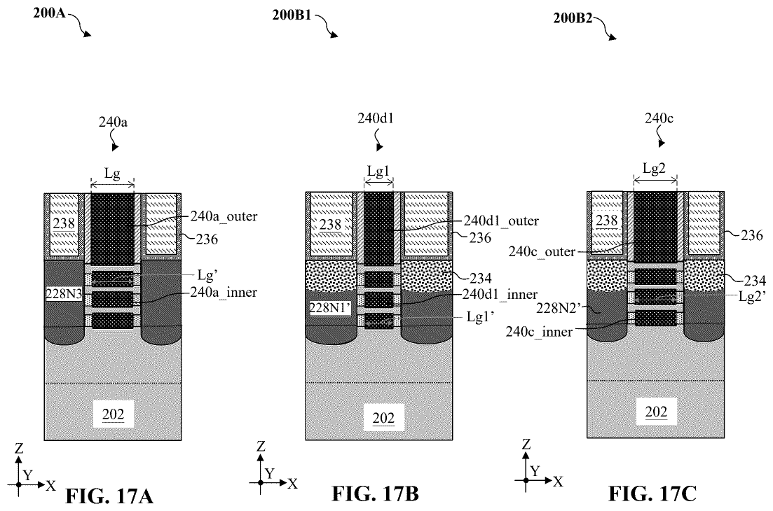

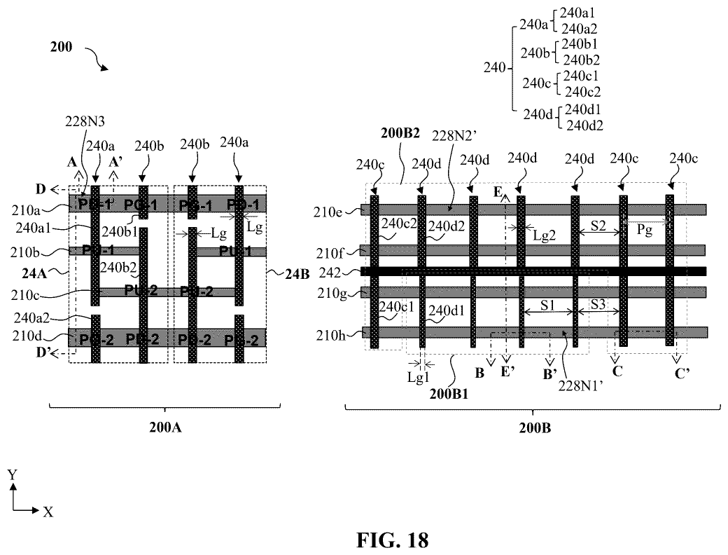

The dummy gate stacks 216 also include dummy gate stacks 216d (shown in FIG. 10) formed in both the region 200B1 and the region 200B2. In an embodiment, the dummy gate stack 216d extends across the boundary between the region 200B1 and the region 200B2 and is formed over at least a channel region 205C of one of the fin-shaped structures 210e-210h in the region 200B1 and at least a channel region 205C of one of the fin-shaped structures 210e-210h in the region 200B2. The dummy gate stacks 216d are formed while using the third portions 213c of the HM layer 213′ as an etch mask. In the present embodiments, dummy gate stacks 216d are defined by a gate length (i.e., width measured along the X-axis) that varies along the Y-axis. That is, the dummy gate stacks 216d have a non-uniform gate length. More specifically, the dummy gate stack 216d includes a portion 216d1 formed in the region 200B1 and having the gate length Lg1 (shown in FIGS. 3 and 10) and a portion 216d2 formed in the region 200B2 and having the gate length Lg2 greater than the gate length Lg1. As discussed above, the change in the gate length of the dummy gate stack 216d along the Y axis affords flexibility in designing metal gate structures (e.g., gate structures 240 shown in FIGS. 17A-17C and 18) having regions of different gate lengths for purposes of adjusting various device parameters (e.g., speed).

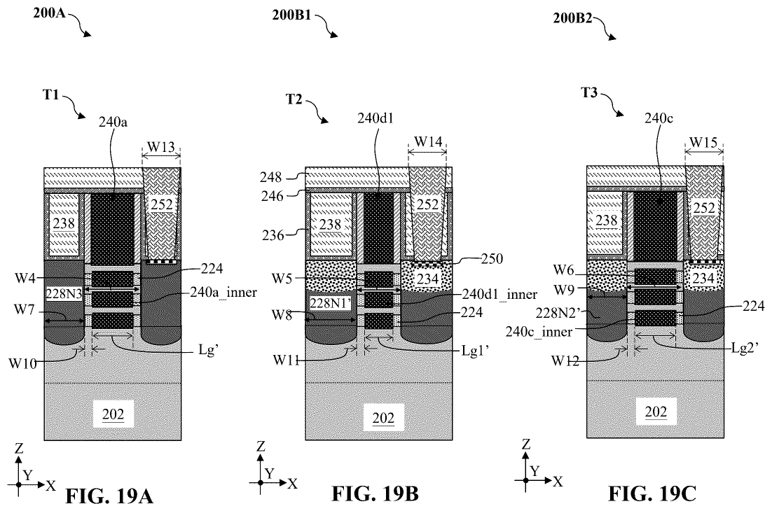

It is noted that, a channel region 205C of the fin-shaped structure 210 refers to a portion of the fin-shaped structure 210 disposed directly under a gate structure thereover, and the gate lengths of the gate structures (e.g., dummy gate stacks 216) define corresponding channel widths of channel regions 205C thereunder. That is, the channel width W5 (shown in FIG. 19B) of the channel region 205C in the region 200B1 is less than the channel width W6 (shown in FIG. 19C) of the channel region 205C in the region 200B2. The channel regions 205C and the dummy gate stacks 216 also define source/drain regions 205SD (shown in FIGS. 11A-11C) that are not vertically overlapped by the dummy gate stacks 216. Each of the channel regions 205C is disposed between two source/drain regions 205SD along the X-axis. In this embodiment, a gate replacement process (or gate-last process) is adopted where the dummy gate stacks 216 serve as placeholders for gate structures 240 (shown in FIGS. 18 and 19A-19C). Other processes and configuration are possible.

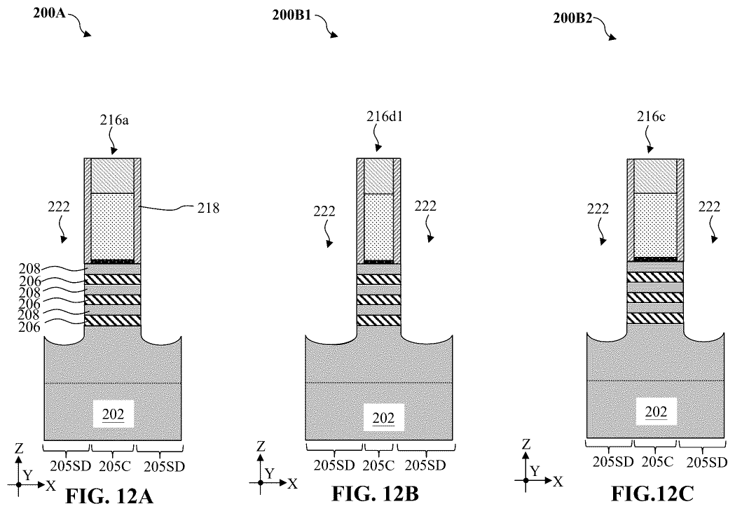

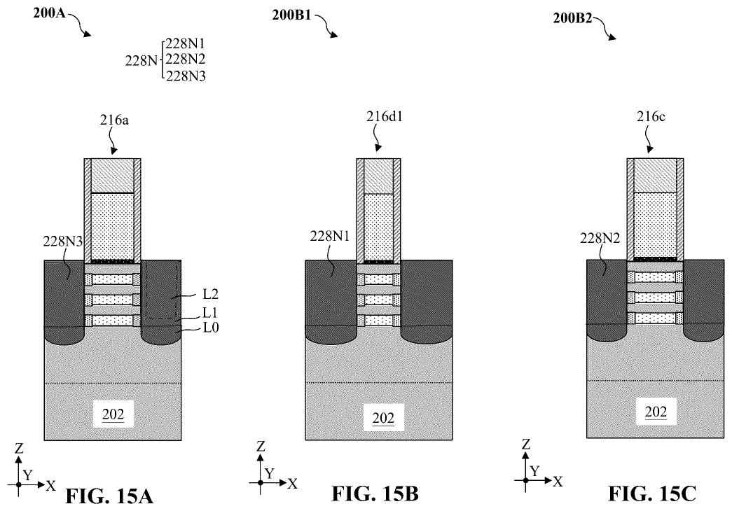

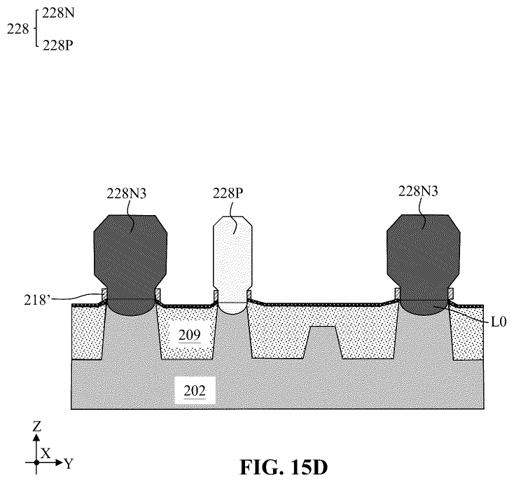

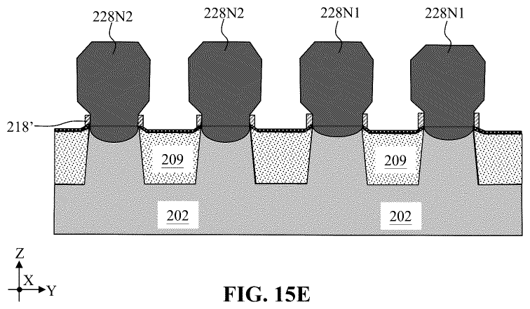

Referring to FIGS. 4 and 12A-12C, method 100 includes a block 108 where source/drain regions 205SD are recessed to form source/drain openings 220. Gate spacers 218 are formed to extend along sidewall surfaces of the dummy gate stacks 216. The gate spacers 218 may include silicon oxide, silicon nitride, silicon carbide, silicon oxynitride, silicon carbonitride, silicon oxycarbide, silicon oxycarbonitride, and/or combinations thereof. The profile of the gate spacer 218 shown in FIGS. 12A-12C is just an example and is not intended to be limiting. For example, in some embodiments, the gate spacer 218 may have a non-uniform width from bottom to top, and a top surface of the gate spacer 218 may be lower than a top surface of the dummy gate stack 216. In some embodiments, the formation of the gate spacer 218 may also form fin sidewall spacers 218′ (shown in FIG. 15D) directly over the isolation features 209 and extending along lower portions of the fin-shaped structures 210.

In some embodiments, the source/drain regions 205SD of the fin-shaped structures 210 that are not covered by the dummy gate stacks 216 and the gate spacers 218 are anisotropically etched by a dry etch or a suitable etching process to form source/drain openings 222. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. The source/drain openings 222 extend through the fin-shaped structures 210 and partially extend into the substrate 202. As illustrated by FIGS. 12A-12C, sidewalls of the channel layers 208 and the sacrificial layers 206 are exposed in the source/drain openings 222.

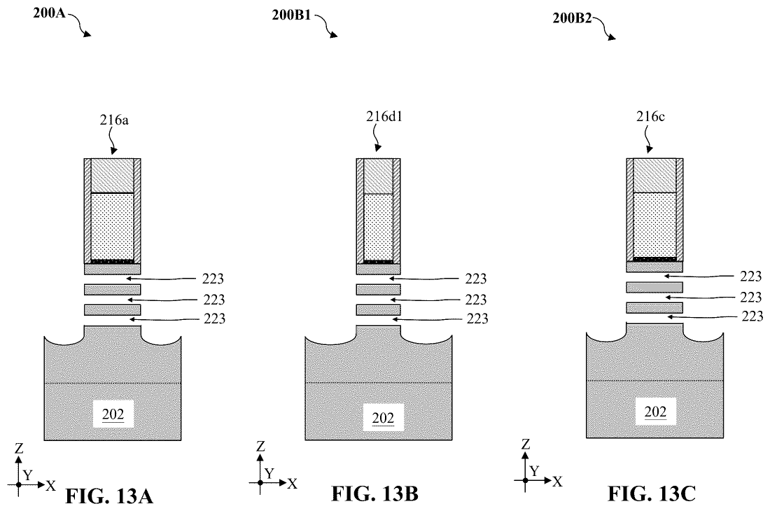

Referring to FIGS. 4, 13A-13C, and 14A-14C, method 100 includes a block 110 where the sacrificial layers 206 are replaced with dummy layers 224. With reference to FIGS. 13A-13C, after the formation of the source/drain openings 222, the sacrificial layers 206 interleaving the channel layers 208 in the channel region 205C are selectively removed. The selective removal of the sacrificial layers 206 releases the channel layers 208 to form channel members 208 and forms spaces 223 between and around adjacent channel members 208. Depending on the design, the channel members 208 may take form of nanowires, nanosheets, or other nanostructures. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

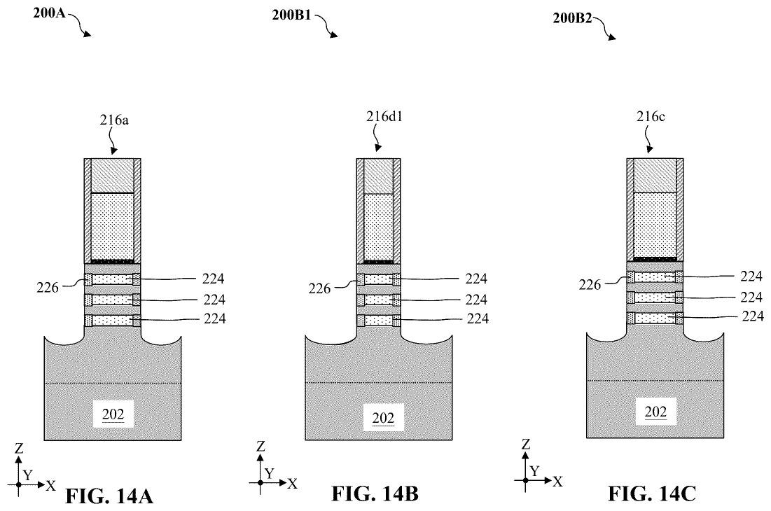

With reference to FIGS. 14A-14C, after the selective removal of the sacrificial layers 206, a dielectric material layer is deposited around the channel members 208 and over the source/drain openings 222 to fill the spaces 223 among the channel members 208. The dielectric material layer may include silicon oxide, silicon nitride, silicon oxynitride, silicon carbonitride, silicon oxycarbonitride, high-K dielectric materials (e.g., aluminum oxide, hafnium oxide), other suitable materials, or combinations thereof, and may be deposited using plasma enhanced chemical vapor deposition (PECVD) or ALD or other suitable methods. In an embodiment, the dielectric material layer includes silicon oxide. In an embodiment, the dielectric material layer extends conformally over the substrate 202. After the deposition of the dielectric material layer, an etching process is performed to selectively etch the dielectric material layer, thereby forming dummy layers 224 interleaved by the channel members 208. The dummy layers 224 partially fill the spaces 223. An etch selectivity between the dummy layers 224 and the protection layer 207 and the is greater than an etch selectively between the dummy layers 224 and the isolation feature 209.

Still referring to FIGS. 4 and 14A-14C, method 100 includes a block 112 where inner spacer features 226 are formed. After forming the dummy layers 224, inner spacer features 226 are formed laterally adjacent to the dummy layers 224. The inner spacer features 226 may include silicon oxide, silicon nitride, silicon oxycarbide, silicon oxycarbonitride, silicon carbonitride, metal nitride, or a suitable dielectric material. The dummy layers 224 and inner spacer features 226 are configured to have different compositions such that the dummy layers 224 may be selectively removed during subsequent fabrication processes.

Referring to FIGS. 4 and 15A-15E, method 100 includes a block 114 where source/drain features 228 are formed in the source/drain openings 222 and adjacent to the channel regions 205C. FIGS. 15A-15E depict fragmentary cross-sectional views of the semiconductor structure 200 taken along line A-A′, B-B′, C-C′, D-D′, E-E′ shown in FIG. 10, respectively. Source/drain feature(s) may refer to a source or a drain, individually or collectively dependent upon the context.

In some embodiments, before forming the source/drain feature 228, an undoped semiconductor layer L0 may be formed in the lower portion of the source/drain opening 222 and over a top surface of the substrate 202 exposed in the source/drain openings 222 by using an epitaxial process. The semiconductor layer L0 may be undoped or not intentionally doped and may include undoped silicon (Si), undoped germanium (Ge), undoped silicon germanium (SiGe), or other suitable materials. In an embodiment, the semiconductor layer L0 includes undoped silicon (Si). Although the semiconductor layer L0 is only illustrated in regions for forming n-type transistors, it is understood that the semiconductor layer L0 may also be formed in regions for forming p-type transistors. The source/drain features 228 are then formed over the semiconductor layer L0 and coupled to the channel members 208 of the channel regions 205C and each may be epitaxially and selectively formed from exposed semiconductor surfaces by using an epitaxial process, such as vapor phase epitaxy (VPE), ultrahigh vacuum chemical vapor deposition (UHV-CVD), molecular-beam epitaxy (MBE), and/or other suitable processes.

The source/drain features 228 include n-type source/drain features 228N for forming n-type transistors. In this embodiment, the n-type source/drain features 228N of the semiconductor structure 200 includes n-type source/drain features 228N1 formed in the region 200B1, n-type source/drain features 228N2 formed in the region 200B2, and n-type source/drain features 228N3 formed in the region 200A forming pull-down transistors PD-1 and PD-2 and the pass-gate transistors PG-1 and PG-2. Example n-type source/drain features 228N may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process.

In some embodiments, each of the n-type source/drain features 228N may include multiple doped semiconductor layers, such as doped semiconductor layers L1, L2 illustrated in FIG. 15A, with different doping concentrations. For instance, each of the n-type source/drain features 228N includes a first doped semiconductor layer L1 having a first dopant concentration and a second doped semiconductor layer L2 having a second dopant concentration greater than the first dopant concentration. The second doped semiconductor layer L2 is formed after the formation of the first doped semiconductor layer L1. In an embodiment, dopant of the doped semiconductor layers L1, L2 of the n-type source/drain features 228N includes phosphorus, arsenic, antimony and/or other group V elements. In an embodiment, at this stage, the source/drain features 228N1, 228N2, 228N3 are formed simultaneously and have a same dopant concentration profile.

The source/drain features 228 also include p-type source/drain features such as p-type source/drain features 228P formed in the region 200A for forming pull-up transistors PU-1 and PU-2 and the read-port pass gate transistor R-PG of the SRAM cell. Although not shown, the region 200B1 and/or region 200B2 may also include p-type source/drain features that may be formed simultaneously with the source/drain features 228P. Example p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

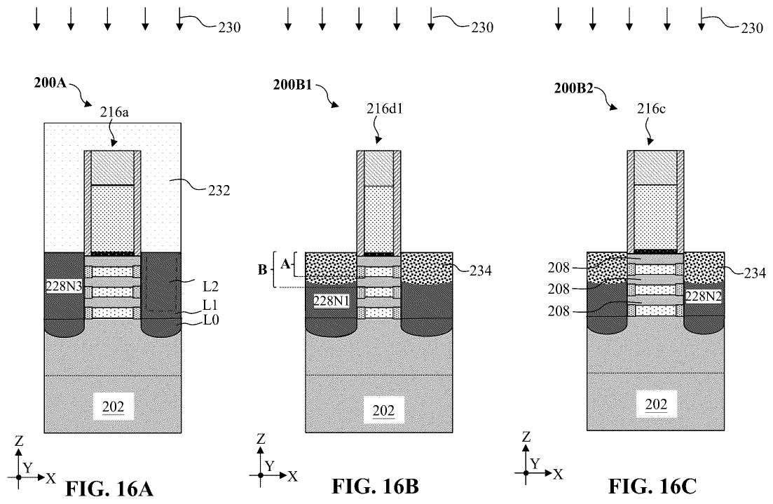

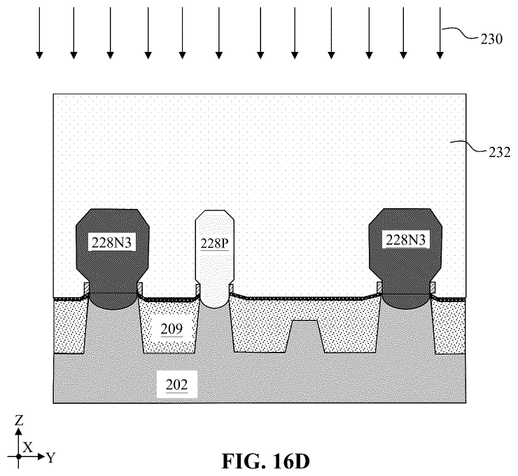

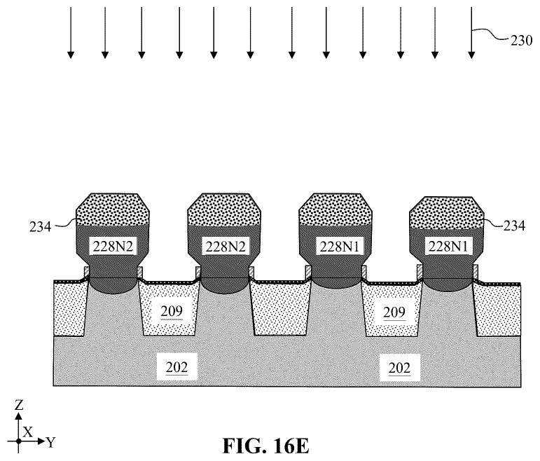

Referring to FIGS. 4 and 16A-16E, method 100 includes a block 116 where an ion implantation process 230 is performed to the semiconductor structure 200. A patterned protection layer 232 is formed over the substrate 202. In an embodiment, the patterned protection layer 232 may include a photoresist layer and may be formed by a combination of photolithography process (e.g., coating, pre-exposure baking, exposure, post-exposure baking process, developing process). The patterned protection layer 232 includes one or more openings configured to define regions that will undergo the ion implantation process 230 while other regions are protected by the patterned protection layer 232. In this illustrated embodiment, the patterned protection layer 232 has openings exposing the n-type source/drain features 228N1 in the region 200B1 and n-type source/drain features 228N2 in the region 200B2. The n-type source/drain features 228N3 in the region 200A and all p-type source/drain features 228P over the substrate 202 are covered by the patterned protection layer 232.

While using the patterned protection layer 232 as a doping mask, the ion implantation process 230 is performed to the semiconductor structure 200. The patterned protection layer 232 may be selectively removed after the performing of the ion implantation process 230. In this illustrated embodiment, the ion implantation process 230 is performed to dope the n-type source/drain features 228N1 and 228N2, while the n-type source/drain features 222N3 and p-type source/drain features 228P are covered. In some embodiments, the ion implantation process 230 includes doping phosphorus, arsenic, antimony, other group V elements, and/or combinations thereof. In an embodiment, the n-type source/drain features 228N includes phosphorus as dopants, and the dopant of the ion implantation process 230 also includes phosphorus. In another embodiment, the ion implantation process 230 dopes an n-type dopant (e.g., phosphorus) different than dopant (e.g., arsenic) of the n-type source/drain features 228N formed at block 114. The formation of the doped region 234 increases dopant concentrations of the source/drain features 228N1 and 228N2 in the region 200B and reduce parasitic resistances, thereby increasing the saturation current Iₛₐₜ of n-type transistors in the region 200B and thus the speed of the n-type transistors in the region 200B.

The ion implantation process 230 provides relatively heavy and shallow doping on a top portion of the n-type source/drain features 228N1 and 228N2 exposed by the patterned protection layer 232, thereby forming doped regions 234 in the n-type source/drain features 228N1 and 228N2. To avoid high sub-threshold voltage and current leakage, the doped region 234 does not extend into a depth near the bottommost channel member 208 of the channel members. Parameters of the ion implantation process 230 for forming the doped regions 234 may be adjusted. For example, region A (shown in FIG. 16B) in the source/drain feature 228N1/228N2 is defined as a region between a top surface of the source/drain feature 228N1/228N2 and a top surface of the channel member 208 (e.g., the middle channel member 208) disposed immediately under the topmost channel member 208. Region B (shown in FIG. 16B) in the source/drain feature 228N1/228N2 is defined as a region between a top surface of the source/drain feature 228N1/228N2 and a bottom surface of the channel member 208 (e.g., the middle channel member 208) disposed immediately under the topmost channel member 208. In one embodiment, to mainly drive dopants to form the doped region 234 within the region A, the ion implantation process 230 implants the dopant species using implant energy in a range from about 2 KeV to about 3 KeV and the implant dosage is in a range from about 1×10¹⁵ atoms/cm² to about 5×10¹⁵ atoms/cm². In one embodiment, to mainly drive dopants to form the doped region 258 within the region B, the ion implantation process 230 implants the dopant species using implant energy in a range from about 3 KeV to about 4 KeV and the implant dosage is in a range from about 1×10¹⁵ atoms/cm² to about 5×10¹⁵ atoms/cm². If the implant energy is greater than 4 KeV, the doped region 234 may be too close to the bottommost channel member 208, increasing the risk of having an undesired high sub-threshold voltage and current leakage.

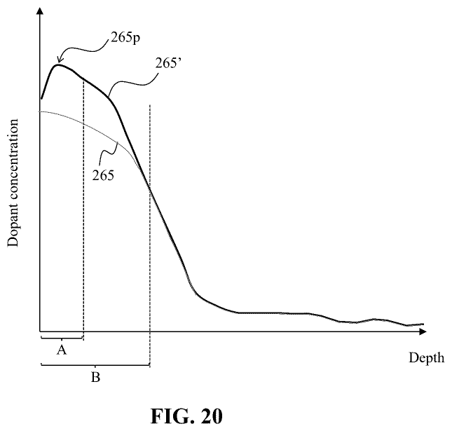

The source/drain feature 228N1 including the doped regions 234 may be referred to as the source/drain feature 228N1′, and the source/drain feature 228N2 including the doped regions 234 may be referred to as the source/drain feature 228N2′. FIG. 20 illustrates a curve 265′ representing a dopant concentration profile of dopants within the source/drain feature 228N1′/228N2′ and a curve 265 representing a dopant concentration profile of dopants within the source/drain feature 228N1/228N2/228N3. As indicated by the curve 265′, dopants of the source/drain feature 228N1′/228N2′ have a gradient profile. The curve 265′ includes a peak 265p near the top surface of the source/drain feature 228N1′/228N2′ and within the region A. It is understood that parameters of the ion implantation process 230 may be adjusted if the transistors have a different number (e.g., 4-10) of channel members 208.

Referring to FIGS. 4 and 17A-17C, method 100 includes a block 118 where a contact etch stop layer (CESL) 236 and an interlayer dielectric (ILD) layer 238 are formed over the substrate 202. After forming the doped regions 234, a contact etch stop layer (CESL) 236 and an interlayer dielectric (ILD) layer 238 are deposited over the substrate 202. The CESL 236 may include silicon nitride, silicon oxynitride, and/or other materials known in the art and may be formed by ALD, plasma-enhanced chemical vapor deposition (PECVD) process and/or other suitable deposition or oxidation processes. As shown in FIG. 9a, the CESL 236 may be deposited on top surfaces of the source/drain features 228 and sidewalls of the gate spacers 218. A portion of the CESL 236 extends along a sidewall of the gate spacer 218 such that the gate spacer 218 is between the gate structure 240 (shown in FIGS. 17A-17C and 18) and the CESL 236. The ILD layer 238 may be deposited by a PECVD process or other suitable deposition technique after the deposition of the CESL 236. The ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. A planarization process (e.g., chemical mechanical polishing (CMP)) may be performed to remove excess materials (e.g., the hard mask layer 213′ and portions of the ILD layer 238 and the CESL 236) to expose top surfaces of the patterned dummy gate electrode layer 212.

Referring to FIGS. 4, 17A-17C, and 18, method 100 includes a block 120 where the dummy gate stacks 216 and the dummy layers 224 are replaced by gate structures 240. With the exposure of the dummy gate electrode layer 212, the dummy gate stacks 216 are selectively removed to form gate trenches (now filled by outer portions (e.g., 240a_outer, 240d1_outer, 240c_outer shown in FIGS. 17A-17C) of the gate structures 240). The removal of the dummy gate stacks 216 may include one or more etching process that are selective to the material in the dummy gate stacks 216. For example, the removal of the dummy gate stacks 216 may be performed using a selective wet etch, a selective dry etch, or a combination thereof. After the removal of the dummy gate stacks 216, the dummy layers 224 are selectively removed to form gate openings (now filled by inner portions (e.g., 240a_inner, 240d1_inner, 240c_inner shown in FIGS. 17A-17C) of the gate structures 240 without substantially etching features such as the protection layer 207. The selective removal of the dummy layers 224 may be implemented by a selective dry etch, a selective wet etch, or other selective etching process.

The gate structures 240 are then formed in the gate trenches and gate openings to wrap around each of the channel members 208 as shown in FIGS. 17A-17C. While not explicitly shown, each of the gate structures 240 includes a gate dielectric layer (not separately labeled) and a gate electrode layer (not separately labeled) over the gate dielectric layer. In an embodiment, a dielectric constant of the gate dielectric layer is greater than a dielectric constant of the gate spacer 218. The gate dielectric layer may include a first dielectric material and the gate spacer 218 may include a second dielectric material, and an ability to store electrical energy of the first dielectric material is greater than an ability to store electrical energy of the second dielectric material. In various embodiments, a thickness of the gate spacer 218 is greater than a thickness of the gate dielectric layer. In some embodiments, the gate dielectric layer includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. A low-k dielectric layer refers to a dielectric material having a dielectric constant no greater than that of silicon dioxide. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material. The gate electrode layer is then deposited over the gate dielectric layer using ALD, PVD, CVD, e-beam evaporation, or other suitable methods. The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the marco 20 includes n-type transistors and p-type transistors, different gate electrode layers may be formed separately for n-type transistors and p-type transistors, which may include different work function metal layers (e.g., for providing different n-type and p-type work function metal layers).

The gate structures 240 include gate structures 240a and 240b formed in the region 200A. The gate structures 240a replace the dummy gate stacks 216a and the dummy layers 224 thereunder. More specifically, the gate structure 240a includes an outer portion 240a_outer replacing the dummy gate stack 216a in the gate trench and an inner portion 240a_inner replacing the dummy layers 224 in the gate openings. The outer portion 240a_outer has the gate length Lg. The inner portion 240a_inner has a gate length Lg′. Similarly, the gate structure 240b includes an outer portion replacing the dummy gate stack 216b and formed over the channel members 208 and in the gate trench and an inner portion replacing the dummy layer 224 under the dummy gate stack 216b.

The gate structures 240 also include gate structures 240c formed in the region 200B2. The gate structures 240c replace the dummy gate stacks 216c and the dummy layers 224 thereunder. More specifically, the gate structure 240c includes an outer portion 240c_outer replacing the dummy gate stack 216c in the gate trench and an inner portion 240c_inner replacing the dummy layers 224 under the dummy gate stack 216c and formed in the gate openings. The outer portion 240c_outer has the gate length Lg2. The inner portion 240c_inner has the gate length Lg2′. In an embodiment, the gate length Lg2′ is greater than the gate length Lg1′. The gate length Lg2′ may be equal to the gate length Lg′, the gate length Lg2 may be equal to the gate length Lg.

The gate structures 240 also include gate structures 240d formed in both the region 200B1 and the region 200B2. The gate structures 240d replace the dummy gate stacks 216d and the dummy layers 224 thereunder. More specifically, the gate structure 240d includes a first portion 240d1 in the region 200B1 and replacing the portion 216d1 of the dummy gate stack 216d and the dummy layers 224 thereunder and a second portion 240d2 in the region 200B2 and replacing the portion 216d2 of the dummy gate stack 216d and the dummy layers 224 thereunder. The first portion 240d1 of the gate structure 240d includes an outer portion 240d1_outer replacing the portion 216d1 and formed over the channel members 208 and in the gate trench and an inner portion 240d1_inner replacing the dummy layers 224 under the dummy gate stack 216c and formed in the gate openings. The outer portion 240d1_outer has the gate length Lg1. The inner portion 240d1_inner has the gate length Lg1′. The second portion 240d2 of the gate structure 240d includes an outer portion replacing the dummy gate stack 216d2 and formed over the channel members 208 and in the gate trench and an inner portion replacing the dummy layers 224 under the portion 216d2 and formed in the gate openings. The outer portion of the second portion 240d2 of the gate structure 240d is substantially the same as the outer portion 240c_outer and has the gate length Lg2. The inner portion of the second portion 240d2 of the gate structure 240d is substantially the same as the inner portion 240c_inner and has the gate length Lg2′. As described above, the gate length Lg is greater than the gate length Lg1, and the gate length Lg2 is greater than the gate length Lg1. In an embodiment, Lg is equal to Lg2. In an embodiment, a ratio of the gate length Lg1 to the gate length Lg2 (i.e., Lg1/Lg2) is less than 1 and greater than about 0.5. If the ratio is no less than 0.5, the gate length Lg1 may be too small, adversely leading to increased short-channel effect (e.g., Drain-Induced Barrier Lowering (DIBL) effect) and threshold voltage variation. In an embodiment, the ratio is greater than 0.9 and less than 1. In some embodiments, a gate length difference (i.e., Δ Lg) between the gate length Lg2 and the gate length Lg1 is between about 0.5 nm and about 5 nm.

To fulfill desired functions in the region 200A, each of the gate structures 240a-240b are cut, by first gate isolation structures (not physically shown), into two segments. Each gate structure 240 extends lengthwise along a first direction (e.g., the Y direction). Gate spacer 218 extends along a sidewall of the gate structure 240 and lengthwise along the first direction. The first gate isolation structure may extend lengthwise along a second direction (e.g., the X direction) different from the first direction. In this illustrated embodiment, the gate structure 240a includes two physically isolated segments 240al and 240a2 (shown in FIG. 18). The segment 240al extends over the fin-shaped structures 210a and 210b and functions as gate structures of the pull-down transistor PD-1 and pull-down transistor PU-1. The segment 240a2 extends over the fin-shaped structure 210d and functions as the gate structure of the pass-gate transistor PG-2. The gate structure 240b includes two physically isolated segments 240b1 and 240b2. The segment 240bl extends over the fin-shaped structure 210a and functions as the gate structure of the pass-gate transistor PG-1. The segment 240b2 extends over the fin-shaped structures 210c and 210d and functions as the gate structures of the pull-down transistor PD-2 and pull-down transistor PU-2.

In this illustrated embodiment, to fulfill desired functions in the region 200B, one or more of the gate structures 240c-240d may also be cut, by second gate isolation structures 242, into two segments. The first gate isolation structures and the second gate isolation structures 242 may be formed before or after the formation of the gate structures 240. The gate structure 240c includes two physically isolated segments 240cl and 240c2 both in the region 200B1. Each of the segments 240cl and 240c2 has the gate length Lg2. The gate structure 240d includes two physically isolated segments 240d1 and 240d2. The segment 240d1 having the gate length Lg1 is formed in the region 200B1 and the segment 240d2 having the gate length Lg2 is formed in the region 200B2. In an embodiment, the segment 240d2 is substantially the same as the segment 240c2. A center line of the segment 240d2 is aligned with a center line of the segment 240d1.

In the present embodiment represented by FIG. 18, gate structures and segments of the gate structures 240 in the region 200B have a uniform gate pitch Pg. Due to the fixed gate pitch Pg and non-uniform gate lengths, spacings between two adjacent gate structures or segments vary. For instance, two segments 240d1 in the region 200B1 are separated by a spacing S1, two segments 240d1 in the region 200B2 are separated by a spacing S2, and the segment 240d1 in the region 200B1 is separated from the segment 240C1 in the region 200B2 by a spacing S3, and S1>S3>S2.

Upon completion of fabrication of the gate structures 240, transistors such as transistors T1, T2, T3 (shown in FIGS. 19A-19C) having different configurations are formed in the region 200A, 200B 1, and 200B2, respectively. With reference to FIGS. 18A-18C and 19A-19C, the region 200A includes n-type transistors T1 functioning as pull-down transistors or pass-gate transistors in a SRAM cell. For example, the transistor T1 includes the gate structure 240 having the inner portion 240a_inner with the gate length Lg′, channel members 208 spanning a width W4, source/drain feature 228N3 spanning a width W7, and inner spacer features 226 spanning a width W10. The transistor T2 in the region 200B1 includes the segment 240d1 having the inner portion 240d1 inner with the gate length Lg1′, channel members 208 spanning a width W5, source/drain feature 228N1′ spanning a width W8, and inner spacer features 226 spanning a width W11. The transistor T3 in the region 200B2 includes the gate structure 240c having the inner portion 240c_inner with the gate length Lg2′, channel members 208 spanning a width W6, source/drain feature 228N2′ spanning a width W9, and inner spacer features 226 spanning a width W12. By forming gate structures or gate segments with different gate lengths, some transistors (e.g., transistors T2 having the reduced gate length Lg1) may be operated at a higher speed and a higher voltage (e.g., 1.2V), and some other transistors (e.g., transistors T3 having the gate length Lg2) may consume less power. FIG. 21 depicts simulation results of performances of two ring oscillators 290B 1 and 290B2. The difference between the two ring oscillators 290B1 and 290B2 includes that, the ring oscillator 290B1 includes n-type transistors T2 having the reduced gate length Lg1, and the ring oscillator 290B2 includes n-type transistors T3 having the gate length Lg2. As represented by the simulation results, ring oscillator speed of the ring oscillator including the n-type transistors T2 may be improved by about 4% to about 10%.

In an embodiment, the width W4 and the width W6 are greater than the width W5, the width W8 is greater than the width W7 and the width W9. In an embodiment, a width difference (i.e., ΔW) between the width W8 of the source/drain feature 228N1′ and the width W9 of the source/drain feature 228N2′ is between about 0.5 nm and about 5 nm. A ratio of the width difference ΔW to the gate length difference ΔLg (i.e., ΔW/ΔLg) may be in a range between about 0.5 and 1.5. In an embodiment, the width W10 is equal to the width W11 and the width W12. In an embodiment, dimensional configurations of the n-type transistors T1 may be substantially the same as the transistor T3.

Referring to FIGS. 4 and 19A-19C, method 100 includes a block 122 where further processes are performed. Such further processes may include forming an etch stop layer 246 over the gate structures 240 and forming an ILD layer 248 over the etch stop layer 246. Compositions and formations of the etch stop layer 246 and the ILD layer 248 may be similar to those of the CESL 236 and ILD layer 238, respectively, and repeated description is omitted for reason of simplicity. Then, silicide layers 250 and source/drain contacts 252 may be formed to couple to the source/drain features 228. The source/drain contacts 252 extend through the etch stop layers 236 and 246 and the ILD layers 238 and 248 and may include aluminum (Al), copper (Cu), tungsten (W), cobalt (Co), ruthenium (Ru), or molybdenum (Mo) or other suitable materials. Although not shown, in some embodiments, the source/drain contacts 252 may further include a barrier layer (e.g., TiN, TaN).

The region 200A includes silicide layers 250 in direct contact with source/drain feature 228N3, the region 200B1 includes silicide layers 250 in direct contact with the doped region 234 in the source/drain feature 2228N1′, and the region 200B2 includes silicide layers 250 in direct contact with the doped region 234 in the source/drain feature 228N2′. For embodiments in which the doped regions 234 include dopants formed of phosphorus, concentration of phosphorus at the interface between the source/drain features (e.g., 228N1′ and 228N2′) in the region 200B and the silicide layers 250 thereover may be higher than concentration of phosphorus at the interface between the source/drain features (e.g., 228N3) in the region 200A and the silicide layers 250 thereover. In an embodiment, the silicide layer 250 has a curved profile. In various embodiments, an electrical conductivity of the silicide layer 250 is between an electrical conductivity of the source/drain feature (e.g., the source/drain feature 228N1′, 228N2′, 228N3) and an electrical conductivity of the source/drain contact 252.

The region 200A includes source/drain contact 252 having a width W13, the region 200B1 includes source/drain contact 252 having a width W14, and the region 200B2 includes source/drain contact 252 having a width W15. In an embodiment, the width W14 is greater than the width W13 and the width W15. A width difference (i.e., ΔW′) between the width W14 and the width W15 is less than about 5 nm. A ratio of the width difference ΔW′ to the gate length difference ΔLg (i.e., ΔW′/ΔLg) may be no greater than 3. In another embodiment, the width W14 is equal to the width W13 and the width W15.

After forming the source/drain contacts 252, further processes are performed to finalize the fabrication of the semiconductor structure 200. For example, additional features such as gate vias and interconnect structure(s) may be formed over and/or under the semiconductor structure 200. In some embodiments, the interconnect structure may include multiple intermetal dielectric (IMD) layers and multiple metal lines or contact vias in each of the IMD layers. In some instances, the IMD layers and the ILD layer 238 may share similar composition. The metal lines and contact vias in each IMD layer may be formed of metal, such as aluminum, tungsten, ruthenium, or copper.

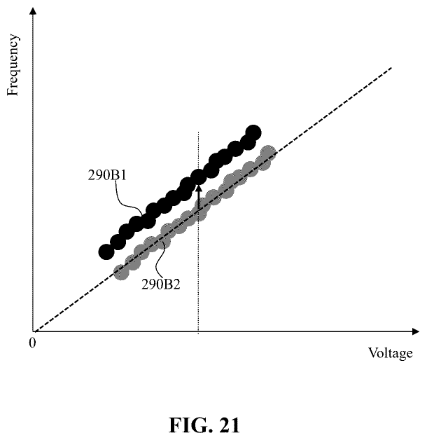

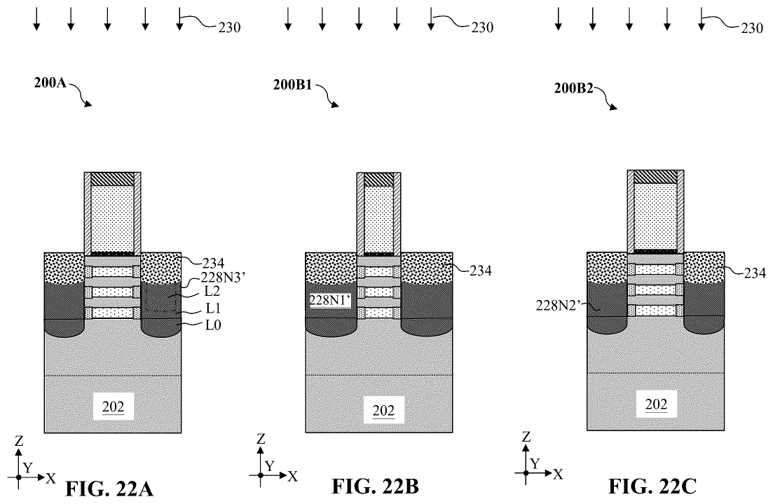

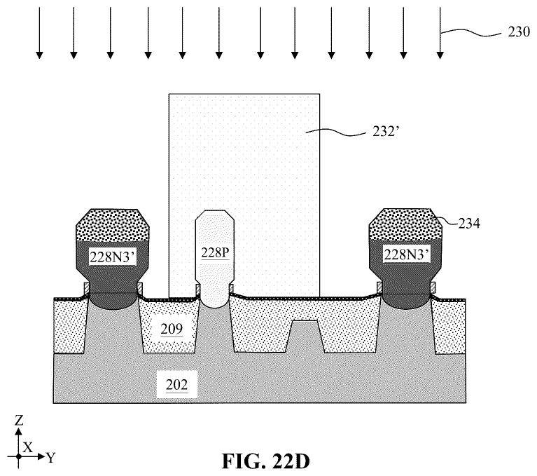

In the above embodiments described with reference to FIGS. 16A-19C, the ion implantation process 230 is performed to form the doped regions 234 in the region 200B. In alternative embodiments represented by FIGS. 22A-27C, doped regions may be formed in the n-type source/drain features 228N3 in the region 200A to improve the performance of the memory array 24.

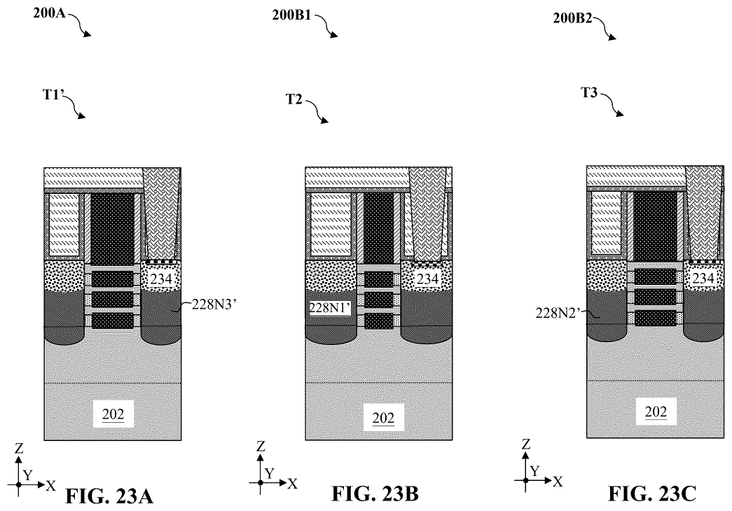

FIGS. 22A-22D and 23A-23C depict fragmentary cross-sectional views of the semiconductor structure 200, according to a first alternative embodiment of the present disclosure. In this alternative embodiment, the semiconductor structure 200 represented by FIGS. 22A-22D is similar to the semiconductor structure 200 represented by FIGS. 16A-16E, and one of the differences between the two semiconductor structures includes that, the semiconductor structure 200 represented by FIGS. 22A-22D includes a patterned protection layer 232′ (shown in FIG. 22D) different from the patterned protection layer 232. More specifically, openings of the patterned protection layer 232′ not only exposes the n-type source/drain features 228N1 in the region 200B1 and n-type source/drain features 228N2 in the region 200B2, but also exposes the n-type source/drain features 228N3 in the region 200A. All p-type source/drain features 228P over the substrate 202 are covered by the patterned protection layer 232′. The ion implantation process 230 is then performed to form the doped regions 234 in the n-type source/drain features 228N1, 228N2, and 228N3. The source/drain feature 228N3 including the doped region 234 is referred to as the source/drain feature 228N3′. Operations in blocks 118-122 are then performed to finish the fabrication of the corresponding semiconductor structure 200 represented by FIGS. 23A-23C. The semiconductor structure 200 represented by FIGS. 23A-23C includes n-type transistors T1′ in the region 200A and the n-type transistors transistor T2 and T3 in the region 200B. Compared to the transistor T1, the transistor T1′ has a more heavily doped source/drain feature 228N3′, a lower parasitic resistance (e.g., a lower contact resistance, a low parasitic resistance related to the source/drain feature 228N3′ itself), a higher saturation current Iₛₐₜ, and improved performance. In some embodiments, the saturation current Iₛₐₜ may be improved by about 4.5%. In an embodiment, dimensional configurations of the n-type transistors T1′ may be substantially the same as the transistor T3, and repeated description is omitted for reason of simplicity.

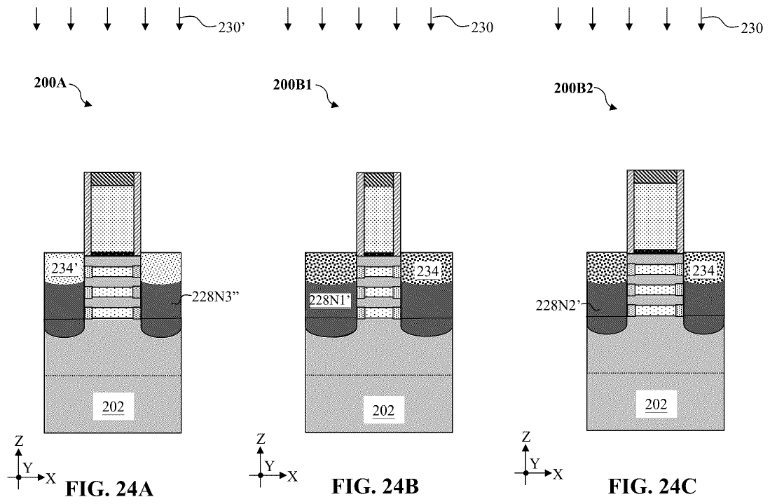

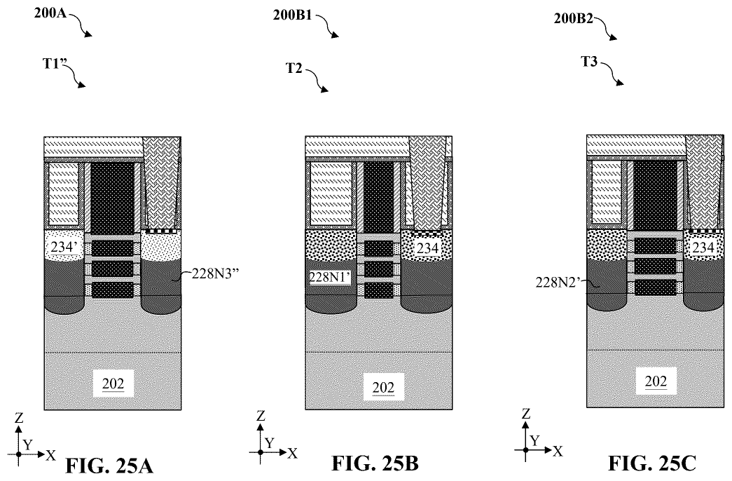

FIGS. 24A-24C and 25A-25C depict fragmentary cross-sectional views of the semiconductor structure 200, according to a second alternative embodiment of the present disclosure. In this second alternative embodiment, the semiconductor structure 200 represented by FIGS. 24A-24C is similar to the semiconductor structure 200 represented by FIGS. 22A-22D, and one of the differences between the two semiconductor structures includes that, the semiconductor structure 200 represented by FIGS. 24A-24C includes a doped region 234′ in the n-type transistors in the region 200A. A dopant concentration of the doped region 234′ is less than a dopant concentration of the doped region 234. This dopant concentration difference may be achieved by implementing two separate ion implantation processes 230′ and 230. For example, the ion implantation process 230 is implemented to form the doped region 234, the ion implantation process 230′ is implemented to form the doped region 234′, and dose (e.g., total number of ions implanted per unit area) of the ion implantation process 230′ is less than that of the ion implantation process 230. In an embodiment, a ratio of the dose of the ion implantation process 230′ to the dose of the ion implantation process 230 is between about 0.6 and about 0.8. If the ratio is less than 0.6, then the dopant concentration of the doped region 234′ may not largely change the dopant concentration profile of the source/drain feature 228N3″ to improve the speed. If the ratio is greater than 0.8, then the operation voltage V_{ccmin} of the SRAM cell may not be improved. It is understood that the ion implantation processes 230′ and 230 may use two doping masks to form the doped region 234′ and 234. The source/drain feature 228N3 including the doped region 234′ is referred to as the source/drain feature 228N3″. Operations in blocks 118-122 are then performed to finish the fabrication of the semiconductor structure 200 represented by FIGS. 25A-25C. The transistor that includes the source/drain feature 228N3″ may be referred to as T1″. Dopant concentration of the source/drain feature 228N3″ is greater than that of the source/drain feature 228N3 and less than that of the source/drain feature 228N3′. Compared to the transistor T1, the transistor T1″ has a more heavily doped source/drain feature 228N3″, a lower parasitic resistance (e.g., a lower contact resistance, a low parasitic resistance related to the source/drain feature 228N3′ itself), a higher saturation current Iₛₐₜ, and improved performance. In some embodiments, the saturation current Iₛₐₜ may be improved by about 4% (e.g., greater than that of the transistor T1 and less than that of the transistor T1′). Compared to SRAM cell including the transistor T1, the speed of the SRAM cell including the transistor T1″ may also increase by about 4%. In addition, operation voltage V_{ccmin} of the SRAM cell including the transistor T1″ may be less than operation voltage V_{ccmin} of the SRAM cell including the transistor T1′ and operation voltage V_{ccmin} of the SRAM cell including the transistor T1. In an embodiment, the operation voltage V_{ccmin} may be reduced by about 20 mV.

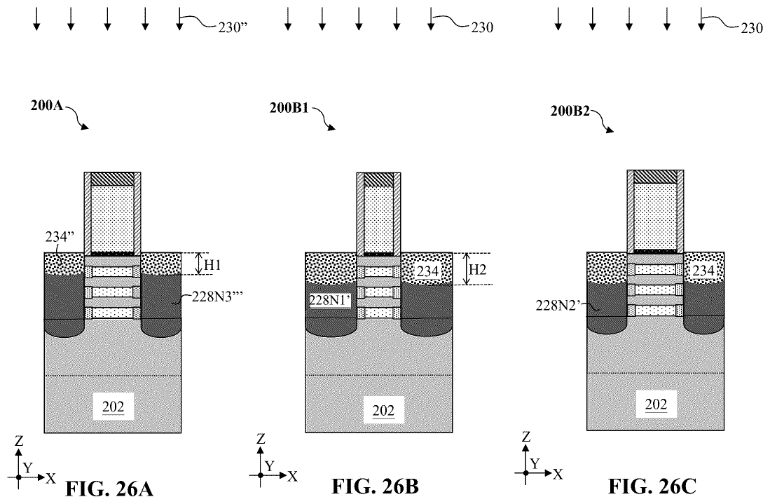

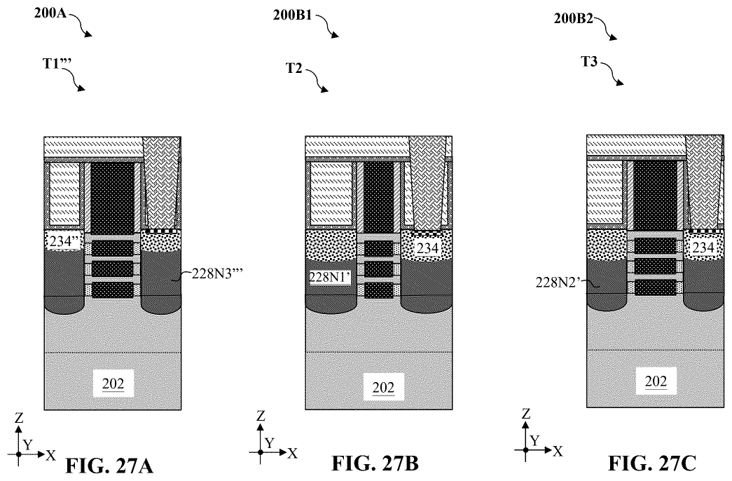

FIGS. 26A-26C and 27A-27C depict fragmentary cross-sectional views of the semiconductor structure 200, according to a third alternative embodiment of the present disclosure. In this alternative embodiment, the semiconductor structure 200 represented by FIGS. 26A-26C is similar to the semiconductor structure 200 represented by FIGS. 22A-22D, and one of the differences between the two semiconductor structures includes that, the semiconductor structure 200 represented by FIGS. 26A-26C includes a doped region 234″ in the n-type transistors in the region 200A. A dopant concentration of the doped region 234″ is substantially the same as that of the doped region 234, and a depth H1 of the doped region 234″ is less than a depth H2 of the doped region 234. This implantation depth difference may be achieved by implementing two separate ion implantation processes 230″ and 230. For example, the ion implantation process 230 is implemented to form the doped region 234, the ion implantation process 230″ is implemented to form the doped region 234″, and implant energy of the ion implantation process 230″ is less than that of the ion implantation process 230. It is understood that the ion implantation processes 230″ and 230 may use two doping masks to form the doped region 234″ and 234. The source/drain feature 228N3 including the doped region 234″ is referred to as the source/drain feature 228N3″. Operations in blocks 118-122 are then performed to finish the fabrication of the semiconductor structure 200 represented by FIGS. 27A-27C. The semiconductor structure 200 represented by FIGS. 27A-27C includes n-type transistors T1′″ in the region 200A and the n-type transistors transistor T2 and T3 in the region 200B. The performance of the transistor T1′″ may be substantially the same as the performance of the transistor T1″, and repeated description is omitted for reason of simplicity.

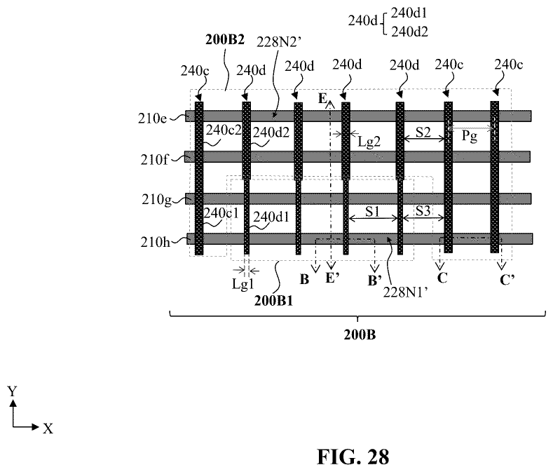

In the above embodiments described with reference to FIG. 18, one or more second gate isolation structures 242 are formed to cut the gate structures 240 in region 200B into segments. For example, the gate structure 240d is cut into segment 240d1 having the gate length Lg1 and segment 240d2 having the gate length Lg2. In another embodiment represented by FIG. 28, the segment 240d1 having the gate length Lg1 and segment 240d2 having the gate length Lg2 are not physically isolated.

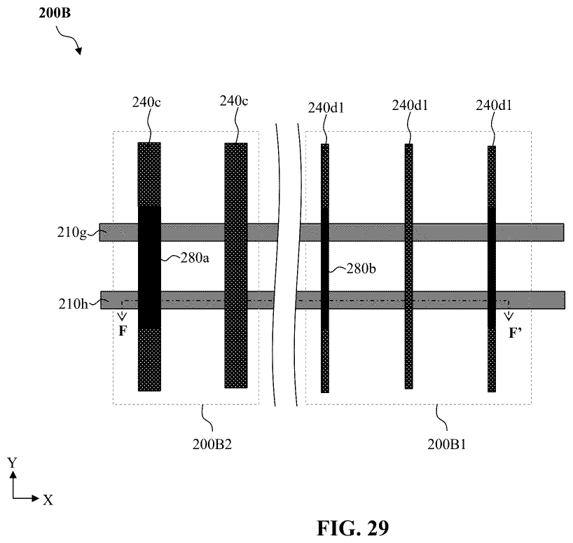

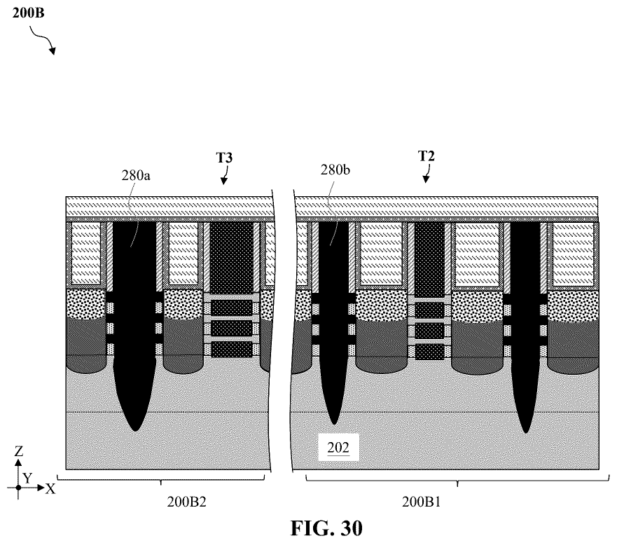

In another alternative embodiment represented by FIGS. 29-30, the region 200B also includes continuous-poly-on-diffusion-edge (CPODE) features 280a and/or 280b configured to cut one or more of the active regions 210e-210h. FIG. 29 depicts a fragmentary top view of the region 200B having CPODE features, and FIG. 30 depicts a fragmentary cross-sectional view of the region 200B taken along line F-F′ shown in FIG. 29. The CPODE features 280a and 280b are formed in a continuous-poly-on-diffusion-edge (CPODE) process. For purposes of this disclosure, a “diffusion edge” may be equivalently referred to as an active edge, where for example an active edge abuts adjacent active regions. In an example process, an etching process is performed to remove a portion of the dummy gate stack 216 and the channel region of the active region under that portion of the dummy gate stack 216, thereby forming a CPODE trench. The dielectric material filling the CPODE trench for isolation is referred to as a CPODE feature. In some embodiments, after the CPODE features are formed, the remaining dummy gate stacks 216 are replaced by metal gate structures 240 in a replacement gate (gate-last) process. In an illustrated embodiment represented by FIGS. 29 and 30, the CPODE feature 280a is formed adjacent to the transistor T3, and the CPODE feature 280b is formed adjacent to the transistor T2. The CPODE feature 280a formed in the region 200B2 spans a width along the X-axis greater than a width of the CPODE feature 280b formed in the region 200B1.

In the above embodiments described with reference to FIGS. 2B-27C, the SRAM array 24 and region 200A including 6T SRAM cells are described. It is noted that the 6T SRAM cell 24A may include a different layout. The inventive concepts (e.g., forming doped region 234/234′/234″ in n-type transistors in the SRAM cell) are also applicable for other SRAM arrays, such as SRAM arrays including a two-port SRAM cell that has seven transistors (7T) or eight transistors (8T).

Although not intended to be limiting, one or more embodiments of the present disclosure provide many benefits to a memory device and the formation thereof. It is understood, however, that other embodiments may offer additional advantages, and not all advantages are necessarily disclosed herein, and that no particular advantage is required for all embodiments. For example, the present disclosure provides a semiconductor device including logic circuits and memory cells. The logic circuits are configured to have transistors with different gate lengths. In an embodiment, the transistors are GAA transistors. By providing transistors with different gate lengths, the logic circuits may obtain have a higher speed (e.g., better ring oscillator speed) while maintaining an acceptable leakage current and satisfactory power consumption. N-type transistors of the logic circuits and n-type transistors of the memory cells may undergo an additional ion implantation process increase dopant concentration of the n-type source/drain features. As a result, the n-type transistors may have improved performance. Various aspects (e.g., speed of the logic circuits, write margin and V_{ccmin} of the memory cells) of the performance of the semiconductor device may be improved.

The present disclosure provides for many different embodiments. Semiconductor structures and methods of fabrication thereof are disclosed herein. In one exemplary aspect, the present disclosure is directed to a method. The method includes forming a first fin and a second fin protruding from a substrate, each of the first fin and the second fin comprising a plurality of channel layers interleaved by a plurality of sacrificial layers, forming a first dummy gate stack over the first fin and a second dummy gate stack over the second fin, wherein the first dummy gate stack has a first gate length, the second dummy gate stack has a second gate length less than the first gate length, after the forming of the first dummy gate stack and the second dummy gate stack, forming a first source/drain trench extending through the first fin and a second source/drain trench extending through the second fin, forming a first source/drain feature in the first source/drain trench and a second source/drain feature in the second source/drain trench, after forming the second source/drain feature, performing an ion implantation process to increase a dopant concentration of an upper portion of the second source/drain feature, and replacing the first dummy gate stack and the plurality of sacrificial layers of the first fin with a first gate structure and replacing the second dummy gate stack and the plurality of sacrificial layers of the second fin with a second gate structure.

In some embodiments, the first gate structure and the second gate structure are portions of a logic cell. In some embodiments, the first gate structure may include a first inner portion disposed under a topmost channel layer of the plurality of channel layers of the first fin and a first outer portion over the first inner portion, the second gate structure may include a second inner portion disposed under a topmost channel layer of the plurality of channel layers of the second fin and a second outer portion over the second inner portion, a gate length of the second outer portion is less than a gate length of the first outer portion. In some embodiments, a gate length of the second inner portion is less than a gate length of the first inner portion. In some embodiments, the replacing of the first dummy gate stack and the plurality of sacrificial layers of the first fin with the first gate structure and the replacing the second dummy gate stack and the plurality of sacrificial layers of the second fin with the second gate structure may include, after forming the first source/drain trench and the second source/drain trench, selectively removing the plurality of sacrificial layers of the first fin and the plurality of sacrificial layers of the second fin, thereby forming gate openings, forming dielectric layers in the gate openings, after forming the first source/drain feature and the second source/drain feature, selectively removing the first dummy gate stack, the second dummy gate stack, and the dielectric layers, and forming the first gate structure wrapping around and over the plurality of channel layers of the first fin and the second gate structure wrapping around and over the plurality of channel layers of the second fin. In some embodiments, the method may also include forming an isolation feature extending between a lower portion of the first fin and a lower portion of the second fin, and forming a protection layer extending over the isolation feature, wherein an etch selectivity between the protection layer and the dielectric layers is greater than an etch selectively between the isolation feature and the dielectric layers. In some embodiments, the second source/drain feature may include n-type dopants. In some embodiments, the performing of the ion implantation process forms a doped region in the second source/drain feature, a bottom boundary of the doped region is above a top surface of a bottommost channel layer of the plurality of channel layers of the second fin. In some embodiments, the first dummy gate stack and the second dummy gate stack are portions of a continuous dummy gate stack, and the method may also include forming an isolation structure providing isolation between the first gate structure and the second gate structure.

In another exemplary aspect, the present disclosure is directed to a method. The method includes forming a first plurality of nanostructures over a substrate in a memory region, forming a first source/drain feature coupled to the first plurality of nanostructures along a first direction, forming a second plurality of nanostructures over the substrate and in a logic region abutting the memory region, wherein the first plurality of nanostructures have a first width along the first direction, the second plurality of nanostructures have a second width along the first direction, the second width is less than the first width, forming a second source/drain feature coupled to the second plurality of nanostructures, wherein the first and second source/drain features comprise dopants, after the forming of the first and second source/drain features, performing an ion implantation process to further dope the first and second source/drain features, forming a first gate structure over the first plurality of nanostructures, and forming a second gate structure over the second plurality of nanostructures.

In some embodiments, the dopants may include first n-type dopants, and the performing of the ion implantation process may include introducing second n-type dopants to upper portions of the first and second source/drain features. In some embodiments, a gate length of the first gate structure is greater than a gate length of the second gate structure. In some embodiments, the method may also include forming a third plurality of nanostructures over the substrate and in the logic region, the third plurality of nanostructures having a third width greater than the second width, prior to the performing of the ion implantation process, forming a third source/drain feature coupled to the third plurality of nanostructures, and forming a third gate structure over the third plurality of nanostructures. In some embodiments, the third width is substantially equal to the first width. In some embodiments, the performing of the ion implantation process may include performing a first ion implantation step to dope the first source/drain feature and performing a second ion implantation step to dope the second source/drain feature, wherein the first ion implantation step and the second ion implantation step comprise different parameters. In some embodiments, a width of the second source/drain feature is different than a width of the first source/drain feature.

In yet another exemplary aspect, the present disclosure is directed to a semiconductor device. The semiconductor device includes a memory cell comprising a first transistor, the first transistor including a first plurality of nanostructures over a substrate, a first gate structure having a first portion over the first plurality of nanostructures and a second portion under a topmost nanostructure of the first plurality of nanostructures, a first n-type source/drain feature coupled to the first plurality of nanostructures, and a logic circuit comprising a second transistor, the second transistor including a second plurality of nanostructures over the substrate, a second gate structure having a first portion over the second plurality of nanostructures and a second portion under a topmost nanostructure of the second plurality of nanostructures, a second n-type source/drain feature coupled to the second plurality of nanostructures, a gate length of the first portion of the first gate structure is greater than a gate length of the first portion of the second gate structure.

In some embodiments, the first n-type source/drain feature and the second n-type source/drain feature may include in-situ doped epitaxial layers, the first transistor further comprises a first doped region embedded in an upper portion of the first n-type source/drain feature, the second transistor further may include a second doped region embedded in an upper portion of the second n-type source/drain feature. In some embodiments, a dopant concentration of the first doped region is less than a dopant concentration of the second doped region. In some embodiments, the first n-type source/drain feature spans a first width, the second n-type source/drain feature spans a second width greater than the first width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first fin and a second fin protruding from a substrate, each of the first fin and the second fin comprising a plurality of channel layers interleaved by a plurality of sacrificial layers;
forming a first dummy gate stack over the first fin and a second dummy gate stack over the second fin, wherein the first dummy gate stack has a first gate length, the second dummy gate stack has a second gate length less than the first gate length;
after the forming of the first dummy gate stack and the second dummy gate stack, forming a first source/drain trench extending through the first fin and a second source/drain trench extending through the second fin;
forming a first source/drain feature in the first source/drain trench and a second source/drain feature in the second source/drain trench;
after forming the second source/drain feature, performing an ion implantation process to increase a dopant concentration of an upper portion of the second source/drain feature; and
replacing the first dummy gate stack and the plurality of sacrificial layers of the first fin with a first gate structure and replacing the second dummy gate stack and the plurality of sacrificial layers of the second fin with a second gate structure.

2. The method of claim 1, wherein the first gate structure and the second gate structure are portions of a logic cell.

3. The method of claim 1, wherein the first gate structure comprises a first inner portion disposed under a topmost channel layer of the plurality of channel layers of the first fin and a first outer portion over the first inner portion, the second gate structure comprises a second inner portion disposed under a topmost channel layer of the plurality of channel layers of the second fin and a second outer portion over the second inner portion, wherein a gate length of the second outer portion is less than a gate length of the first outer portion.

4. The method of claim 3, wherein a gate length of the second inner portion is less than a gate length of the first inner portion.

5. The method of claim 1, wherein the replacing of the first dummy gate stack and the plurality of sacrificial layers of the first fin with the first gate structure and the replacing the second dummy gate stack and the plurality of sacrificial layers of the second fin with the second gate structure comprise:
after forming the first source/drain trench and the second source/drain trench, selectively removing the plurality of sacrificial layers of the first fin and the plurality of sacrificial layers of the second fin, thereby forming gate openings;
forming dielectric layers in the gate openings;
after forming the first source/drain feature and the second source/drain feature, selectively removing the first dummy gate stack, the second dummy gate stack, and the dielectric layers; and
forming the first gate structure wrapping around and over the plurality of channel layers of the first fin and the second gate structure wrapping around and over the plurality of channel layers of the second fin.

6. The method of claim 5, further comprising:
forming an isolation feature extending between a lower portion of the first fin and a lower portion of the second fin; and
forming a protection layer extending over the isolation feature, wherein an etch selectivity between the protection layer and the dielectric layers is greater than an etch selectively between the isolation feature and the dielectric layers.

7. The method of claim 1, wherein the second source/drain feature comprises n-type dopants.

8. The method of claim 1, wherein the performing of the ion implantation process forms a doped region in the second source/drain feature, a bottom boundary of the doped region is above a top surface of a bottommost channel layer of the plurality of channel layers of the second fin.

9. The method of claim 1, wherein the first dummy gate stack and the second dummy gate stack are portions of a continuous dummy gate stack, and the method further comprising:
forming an isolation structure providing isolation between the first gate structure and the second gate structure.

10. A method, comprising:
forming a first plurality of nanostructures over a substrate in a memory region;
forming a first source/drain feature coupled to the first plurality of nanostructures along a first direction;
forming a second plurality of nanostructures over the substrate and in a logic region abutting the memory region, wherein the first plurality of nanostructures have a first width along the first direction, the second plurality of nanostructures have a second width along the first direction, the second width is less than the first width;
forming a second source/drain feature coupled to the second plurality of nanostructures, wherein the first and second source/drain features comprise dopants;
after the forming of the first and second source/drain features, performing an ion implantation process to further dope the first and second source/drain features;
forming a first gate structure over the first plurality of nanostructures; and
forming a second gate structure over the second plurality of nanostructures.

11. The method of claim 10, wherein the dopants comprise first n-type dopants, and the performing of the ion implantation process includes introducing second n-type dopants to upper portions of the first and second source/drain features.

12. The method of claim 10, wherein a gate length of the first gate structure is greater than a gate length of the second gate structure.

13. The method of claim 10, further comprising:
forming a third plurality of nanostructures over the substrate and in the logic region, wherein the third plurality of nanostructures have a third width greater than the second width;
prior to the performing of the ion implantation process, forming a third source/drain feature coupled to the third plurality of nanostructures; and
forming a third gate structure over the third plurality of nanostructures.

14. The method of claim 13, wherein the third width is substantially equal to the first width.

15. The method of claim 10, wherein the performing of the ion implantation process comprises:
performing a first ion implantation step to dope the first source/drain feature; and
performing a second ion implantation step to dope the second source/drain feature, wherein the first ion implantation step and the second ion implantation step comprise different parameters.

16. The method of claim 10, wherein a width of the second source/drain feature is different than a width of the first source/drain feature.

17. A semiconductor device, comprising:
a memory cell comprising a first transistor, the first transistor including:
a first plurality of nanostructures over a substrate,
a first gate structure having a first portion over the first plurality of nanostructures and a second portion under a topmost nanostructure of the first plurality of nanostructures,
a first n-type source/drain feature coupled to the first plurality of nanostructures, and
a logic circuit comprising a second transistor, the second transistor including:
a second plurality of nanostructures over the substrate,
a second gate structure having a first portion over the second plurality of nanostructures and a second portion under a topmost nanostructure of the second plurality of nanostructures, and
a second n-type source/drain feature coupled to the second plurality of nanostructures,
wherein a gate length of the first portion of the first gate structure is greater than a gate length of the first portion of the second gate structure.

18. The semiconductor device of claim 17, wherein the first n-type source/drain feature and the second n-type source/drain feature comprise in-situ doped epitaxial layers, the first transistor further comprises a first doped region embedded in an upper portion of the first n-type source/drain feature, the second transistor further comprises a second doped region embedded in an upper portion of the second n-type source/drain feature.

19. The semiconductor device of claim 18, wherein a dopant concentration of the first doped region is less than a dopant concentration of the second doped region.

20. The semiconductor device of claim 17, wherein the first n-type source/drain feature spans a first width, the second n-type source/drain feature spans a second width greater than the first width.
